(19) United States
(12) Patent Application Publication
(10) Pub. No.: US 2025/0167718 A1
(43) Pub. Date: May 22, 2025

(54) MOTOR CONTROL DEVICE

(71) Applicant: DENSO CORPORATION, Kariya-city (JP)

(72) Inventors: Jun YAMADA, Kariya-city (JP); Daisuke YAMAMOTO, Kariya-city (JP); Hiroki TATEYAMA, Kariya-city (JP); Kenichi OISHI, Kariya-city (JP)

(21) Appl. No.: 19/029,347

(22) Filed: Jan. 17, 2025

Related U.S. Application Data
(63) Continuation of application No. PCT/JP2023/031695, filed on Aug. 31, 2023.

(30) Foreign Application Priority Data
Sep. 21, 2022 (JP) 2022-150083

(51) Int. Cl. H02P 29/024; H02P 23/14

(52) U.S. Cl. CPC H02P 29/0243; H02P 23/14

(57) ABSTRACT

A control unit includes a drive control unit that controls the on and off operation of the switching elements, and an abnormality determination unit that performs abnormality determination on energization paths to the motor windings. The abnormality determination unit identifies a faulted phase, based on voltage detection values when the switching elements of all the phases are turned off, and identifies a permanent energization fault of the faulted phase, based on at least one of a current detection value when one of the switching elements corresponding to the identified faulted phase is turned on, and a rotational position detection value when one or more of the switching elements corresponding to one or more of normal phases are turned on.

### CROSS REFERENCE TO RELATED APPLICATION

The present application is a continuation application of International Patent Application No. PCT/JP2023/031695 filed on Aug. 31, 2023, which designated the U.S. and claims the benefit of priority from Japanese Patent Application No. 2022-150083 filed on Sep. 21, 2022. The entire disclosures of all of the above applications are incorporated herein by reference.

### TECHNICAL FIELD

The present disclosure relates to a motor control device.

### BACKGROUND

A motor control device for controlling a motor has been known.

### SUMMARY

According to an aspect of the present disclosure, a motor control device is configured to control driving of a motor including motor windings of three or more phases.

### BRIEF DESCRIPTION OF THE DRAWINGS

The above object and other objects, features, and advantages of the present disclosure will become more apparent from the following detailed description with reference to the accompanying drawings. In the drawings:

FIG. 1 is a perspective view illustrating a shift-by-wire system according to a first embodiment;

FIG. 2 is a schematic configuration diagram illustrating the shift-by-wire system according to the first embodiment;

FIG. 3 is a circuit diagram for explaining an ECU according to the first embodiment;

FIG. 4 is a schematic diagram illustrating a motor according to the first embodiment;

FIG. 5 is a schematic diagram illustrating an encoder according to the first embodiment;

FIG. 6 is a circuit diagram for explaining a U-phase wire break;

FIG. 7 is a circuit diagram for explaining a short to ground;

FIG. 8 is a circuit diagram for explaining an incomplete short to ground;

FIG. 9 is a flowchart for explaining a faulted phase determination process according to the first embodiment;

FIG. 10 is an explanatory diagram for explaining current when a switching element of a faulted phase is turned on at the time of the incomplete short to ground;

FIG. 11 is an explanatory diagram illustrating current when a switching element of a faulted phase is turned on at the time of the short to ground;

FIG. 12 is an explanatory diagram for explaining magnetic attraction force when a V-phase is energized;

FIG. 13 is an explanatory diagram for explaining the behavior of a rotor when an energization status is switched at the time of a U-phase wire break in the first embodiment;

FIG. 14 is an explanatory diagram for explaining the behavior of the rotor when the energization status is switched at the time of a U-phase wire break in the first embodiment;

FIG. 15 is an explanatory diagram for explaining the behavior of the rotor when the energization status is switched at the time of a U-phase permanent energization fault in the first embodiment;

FIG. 16 is an explanatory diagram for explaining the behavior of the rotor when the energization status is switched at the time of a U-phase permanent energization fault in the first embodiment;

FIG. 17 is an explanatory diagram for explaining rotation angle differences in response to the switching of the energization status according to the first embodiment;

FIG. 18 is a flowchart for explaining an energization process related to fault identification according to the first embodiment;

FIG. 19 is a flowchart for explaining the energization process related to the fault identification according to the first embodiment;

FIG. 20 is a flowchart for explaining a fault condition determination process according to the first embodiment;

FIG. 21 is a time chart for explaining the behavior of the rotor in the energization process according to the first embodiment;

FIG. 22 is a sub-flow for explaining a maximum value update process in an energization status ST13 according to the first embodiment;

FIG. 23 is a sub-flow for explaining a minimum value update process in an energization status ST14 according to the first embodiment;

FIG. 24 is a time chart for explaining a range switching process according to the first embodiment;

FIG. 25 is a map in which energized phase numbers are associated with energized phases according to the first embodiment;

FIG. 26 is a time chart for explaining a process when a stagnation abnormality occurs during the driving of the motor with two normal phases in the first embodiment;

FIG. 27 is a flowchart for explaining an energization process related to fault identification according to a second embodiment;

FIG. 28 is a flowchart for explaining a fault condition determination process according to the second embodiment;

FIG. 29 is a time chart for explaining a range switching process according to the second embodiment;

FIG. 30 is an explanatory diagram for explaining the behavior of a rotor when an energization status is switched at the time of a U-phase wire break in a third embodiment;

FIG. 31 is an explanatory diagram for explaining the behavior of the rotor when the energization status is switched at the time of a U-phase wire break in the third embodiment;

FIG. 32 is an explanatory diagram for explaining the behavior of the rotor when the energization status is switched at the time of a U-phase permanent energization fault in the third embodiment;

FIG. 33 is an explanatory diagram for explaining the behavior of the rotor when the energization status is switched at the time of a U-phase permanent energization fault in the third embodiment;

FIG. 34 is an explanatory diagram for explaining rotation angle differences in response to the switching of the energization status according to the third embodiment;

FIG. 35 is a flowchart for explaining an energization process related to fault identification according to the third embodiment;

FIG. 36 is a flowchart for explaining the energization process related to the fault identification according to the third embodiment;

FIG. 37 is an explanatory diagram for explaining the behavior of a rotor when an energization status is switched at the time of a U-phase wire break in a fourth embodiment;

FIG. 38 is an explanatory diagram for explaining the behavior of the rotor when the energization status is switched at the time of a U-phase wire break in the fourth embodiment;

FIG. 39 is an explanatory diagram for explaining the behavior of the rotor when the energization status is switched at the time of a U-phase permanent energization fault in the fourth embodiment;

FIG. 40 is an explanatory diagram for explaining the behavior of the rotor when the energization status is switched at the time of a U-phase permanent energization fault in the fourth embodiment;

FIG. 41 is a flowchart for explaining a fault condition determination process according to the fourth embodiment;

FIG. 42 is a time chart for explaining the behavior of a rotor when an energization status is switched at the time of a U-phase wire break in a fifth embodiment;

FIG. 43 is a time chart for explaining the behavior of the rotor when the energization status is switched at the time of a U-phase wire break in the fifth embodiment;

FIG. 44 is a time chart for explaining the behavior of the rotor when the energization status is switched at the time of a U-phase permanent energization fault in the fifth embodiment;

FIG. 45 is a flowchart for explaining an energization process related to fault identification according to the fifth embodiment;

FIG. 46 is a flowchart for explaining a fault condition determination process according to the fifth embodiment;

FIG. 47 is a sub-flow for explaining a maximum value and minimum value update process in an energization status ST22 according to the fifth embodiment; and

FIG. 48 is a sub-flow for explaining a maximum value and minimum value update process in an energization status ST23 according to the fifth embodiment.

### DETAILED DESCRIPTION

Hereinafter, examples of the present disclosure will be described.

According to an example of the present disclosure, a motor control device is for controlling driving of a motor. For example, a wire break detection circuit is provided in an energization line of windings of each phase to detect a broken wire. In this case, when switching elements are turned off, the voltage becomes a low level both at the time of a wire break fault and at the time of a short to ground fault, and both cannot be distinguished.

According to an example of the present disclosure, a motor control device is configured to control driving of a motor including motor windings of three or more phases. The motor control device comprises: a drive circuit; and a control unit. The drive circuit includes switching elements configured to turn on and off energization of a corresponding phase of the motor winding. The control unit includes a drive control unit configured to control on and off operation of the switching elements, and an abnormality determination unit configured to perform abnormality determination on an energization path to the motor windings.

The control unit is configured to acquire a voltage detection value detected by a voltage detection unit configured to detect a phase voltage in the motor windings, a current detection value detected by a current detection unit configured to detect a current passing through the motor winding, and a rotational position detection value detected by a rotation detection unit configured to detect a rotational position of the motor.

The abnormality determination unit is configured to identify a faulted phase based on the voltage detection value when the switching elements of all the phases are turned off. The abnormality determination unit is configured to identify a permanent energization fault of the faulted phase, based on at least one of the current detection value when one of the switching elements corresponding to the identified faulted phase is turned on, and the rotational position detection value when a switching element corresponding to one or more normal phases is turned on. Thus, a fault condition can be accurately identified.

### First Embodiment

Hereinafter, a motor control device according to the present disclosure will be described with reference to the drawings. In a plurality of embodiments below, substantially the same components are denoted by the same reference numerals to omit description thereof.

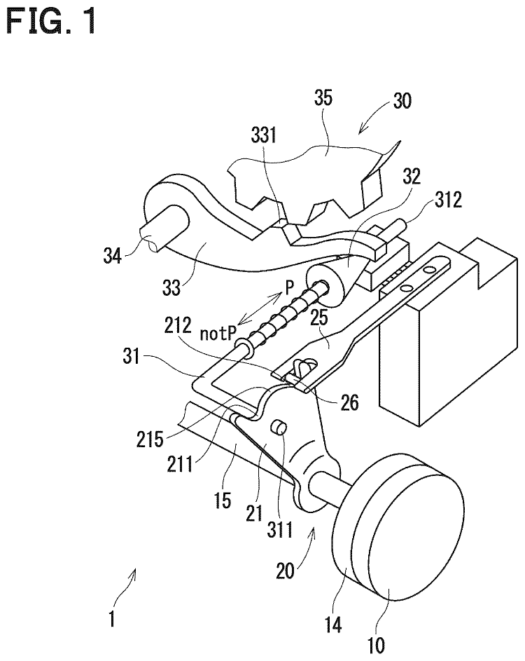

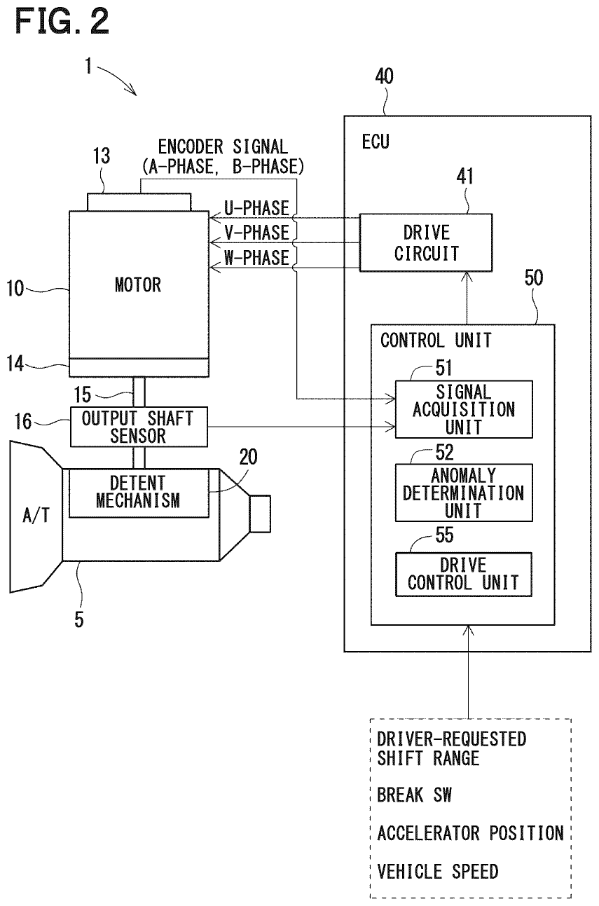

A first embodiment is illustrated in FIGS. 1 to 26. As illustrated in FIGS. 1 and 2, a shift-by-wire system 1 includes a motor 10, a detent mechanism 20, a parking lock mechanism 30, an ECU 40 as a motor control device, etc.

The motor 10 is rotated by power supplied from a battery 90 mounted on a vehicle (not illustrated), to function as a drive source of the detent mechanism 20. The motor 10 is, for example, a switched reluctance motor.

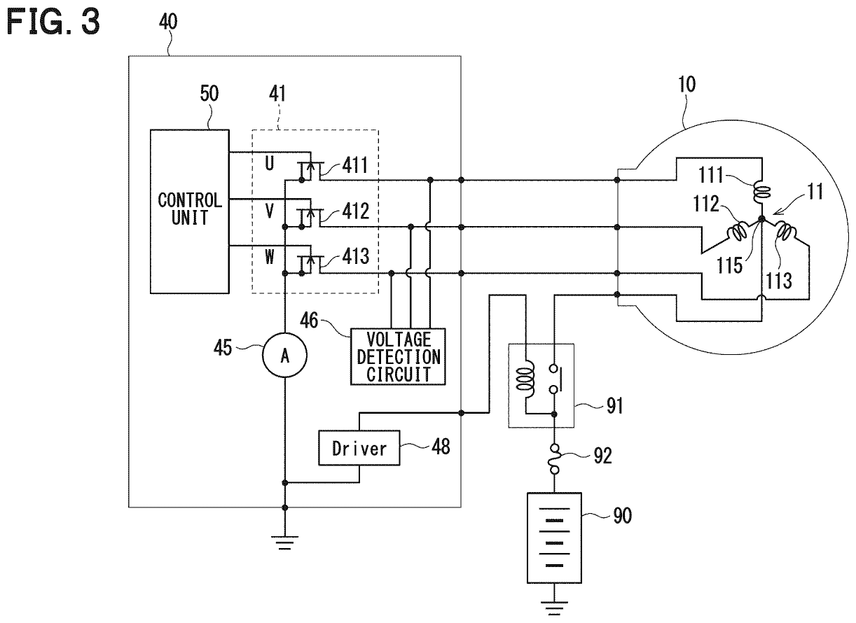

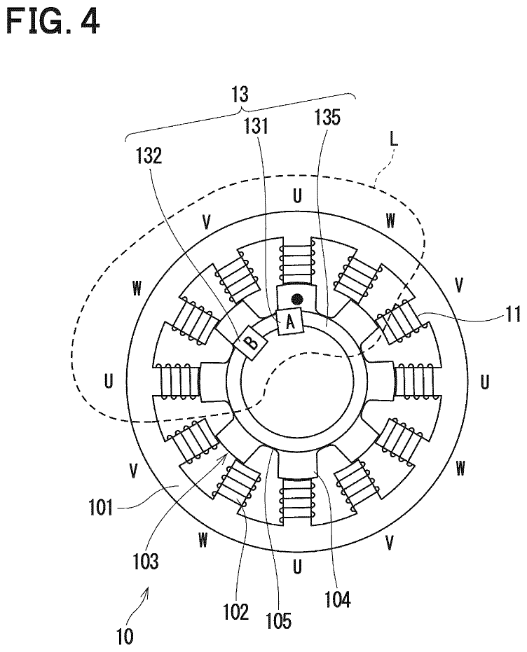

As illustrated in FIGS. 3 and 4, the motor 10 includes a stator 101, a rotor 103, motor windings 11, etc. The motor windings 11 include U-phase coils 111, V-phase coils 112, and W-phase coils 113, and are wound around salient poles 102 of the stator 101. The coils 111 to 113 are connected at a connection 115. The connection 115 is connected to the battery 90 via a motor relay 91 and a fuse 92.

The rotor 103 includes salient poles and is rotatably provided radially inside the stator 101. The rotor 103 is rotationally driven by switching the energized phases of the coils 111 to 113. In the present embodiment, the number of the salient poles of the stator 101 is twelve, and the number of the salient poles of the rotor 103 is eight. Hereinafter, the salient poles of the rotor 103 are referred to as projections 104, and spaces between the projections as recesses 105.

An encoder 13 is a magnetic rotary encoder, and detects the rotational position of the rotor 103. The encoder 13 consists of Hall elements 131 and 132 for magnetic detection, a magnet 135 that rotates together with the rotor 103, etc. The Hall elements 131 and 132 output pulse signals at predetermined angles in synchronization with the rotation of the rotor 103. In the present embodiment, the Hall elements 131 and 132 output signals of Lo when facing north poles and Hi when facing south poles.

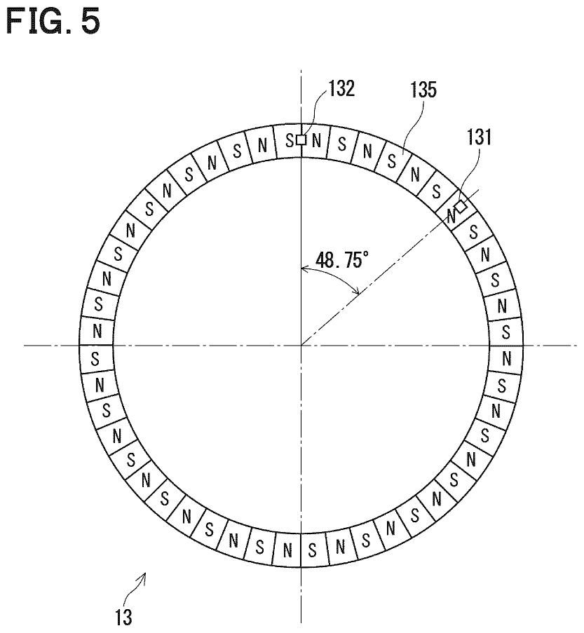

As illustrated in FIG. 5, the magnet 135 is formed in an annular shape and is disposed coaxially with the rotor 103. The magnet 135 is magnetized with north poles and south poles alternated at an equal pitch in a circumferential direction. The magnetization pitch in the present embodiment is 7.5°. This magnetization pitch is equal to the rotation angle of the rotor 103 per excitation of the motor 10. Specifically, in a 1-2 phase excitation mode in which energized phases are switched from the U-phase to the U-phase and V-phases to the V-phase to the V-phase and W-phases to the W-phase to the W-phase and U-phases, when a round of the six switches of the energized phases is performed, the rotor 103 rotates through a mechanical angle of 7.5×6=45°.

The Hall elements 131 and 132 are disposed on the same circumference with a phase difference of an electrical angle of 90°. In the present embodiment, an electrical angle of 90° corresponds to a mechanical angle of 3.75°. The Hall elements 131 and 132 are disposed at a distance of 48.75° apart. In the present embodiment, a signal of the Hall element 131 is referred to as an A-phase, and a signal of the Hall element 132 as a B-phase. The encoder 13 is a two-phase encoder, but may be a three-phase encoder, and may output a Z-phase signal as a reference signal in addition to detection signals.

Returning to FIG. 1, a speed reducer 14 is provided between a motor shaft of the motor 10 and an output shaft 15 to decelerate the rotation of the motor 10 and output the decelerated rotation to the output shaft 15. Thus, the rotation of the motor 10 is transmitted to the detent mechanism 20. An output shaft sensor 16 is, for example, a potentiometer, and detects the rotational position of the output shaft 15 (see FIG. 2).

The detent mechanism 20 includes a detent plate 21, a detent spring 25, and a detent roller 26, and transmits a rotational driving force output from the speed reducer 14 to the parking lock mechanism 30.

The detent plate 21 is fixed to the output shaft 15 and driven by the motor 10. On the detent spring 25 side of the detent plate 21, two valleys 211 and 212 and a crest 215 separating the valleys 211 and 212 are provided.

The detent spring 25 is an elastically deformable plate-shaped member and has a distal end provided with the detent roller 26. The detent spring 25 urges the detent roller 26 toward the rotation center of the detent plate 21.

When torque of a predetermined magnitude or more is applied to the detent plate 21, the detent spring 25 is elastically deformed, and the detent roller 26 moves between the valleys 211 and 212. When the detent roller 26 is fitted into either of the valleys 211 and 212, the swing of the detent plate 21 is restricted, so that the state of the parking lock mechanism 30 and the shift range of an automatic transmission 5 are determined.

The parking lock mechanism 30 includes a parking rod 31, a cone 32, a parking lever 33, a shaft 34, and a parking gear 35. The parking rod 31 is formed in a substantially L shape and is fixed at one end 311 to the detent plate 21. The parking rod 31 is provided at the other end 312 with the cone 32. The cone 32 is formed to contract toward the other end 312. When the detent plate 21 rotates in the direction that causes the detent roller 26 to fit into the valley 211 corresponding to the P range, the cone 32 moves in the direction of an arrow P.

The parking lever 33 abuts on a conical surface of the cone 32 and is swingable about the shaft 34. On the parking gear 35 side of the parking lever 33, a projection 331 that can engage with the parking gear 35 is provided. When the cone 32 moves in the direction of the arrow P due to the rotation of the detent plate 21, the parking lever 33 is pushed up, and the projection 331 engages with the parking gear 35. On the other hand, when the cone 32 moves in the direction of an arrow notP, the engagement of the projection 331 and the parking gear 35 is released.

The parking gear 35 is connected to a drive shaft (not illustrated) and is provided to be able to engage with the projection 331 of the parking lever 33. When the parking gear 35 engages with the projection 331, the rotation of the drive shaft is restricted. When the shift range is a notP range that is a range other than P, the parking gear 35 is not locked by the parking lever 33, and the rotation of the drive shaft is not prevented by the parking lock mechanism 30. When the shift range is the P range, the parking gear 35 is locked by the parking lever 33, and the rotation of the drive shaft is restricted.

As illustrated in FIGS. 2 and 3, the ECU 40 includes a drive circuit 41, a current detection unit 45, a voltage detection circuit 46, a control unit 50, etc. The drive circuit 41 includes three switching elements 411, 412, and 413. The switching elements 411 to 413 are provided in a one-to-one correspondence with the coils 111 to 113 to switch the energization of the corresponding phases. In the present embodiment, the switching elements 411 to 413 are provided between the coils 111 to 113 and ground. The switching elements 411 to 413 of the present embodiment are MOSFETs, but may be IGBTs or the like. The switching elements 411 to 413 are referred to as “MOS” as appropriate in the drawings and the like.

The current detection unit 45 is provided in collective wiring connecting the sources of the switching elements 411 to 413 and ground, to detect the sum of currents flowing through the coils 111 to 113. Hereinafter, current detected by the current detection unit 45 is referred to as a motor current Im. The current detection unit 45 may be provided at any place where currents through the coils 111 to 113 can be detected, and may be provided for each phase.

The voltage detection circuit 46 is connected between the coils 111 to 113 and the switching elements 411 to 413, to detect the terminal voltage of each phase. The relay driver 48 controls the on-off operation of the motor relay 91.

The control unit 50 is mainly composed of a microcomputer or the like, and includes a CPU, ROM, RAM, I/O, a bus line connecting these components, etc., none of which are illustrated. Each process in the control unit 50 may be a software process performed by the CPU executing a program stored in advance in a physical memory device (that is, a readable non-transitory tangible recording medium) such as the ROM, or may be a hardware process performed by a dedicated electronic circuit.

The control unit 50 controls the driving of the motor 10 on the basis of a shift signal corresponding to a driver-requested shift range, a signal from a brake switch, an accelerator position, a vehicle speed, etc., to control the switching of the shift range or the like.

The control unit 50 includes, as functional blocks, a signal acquisition unit 51, an abnormality determination unit 52, a drive control unit 55, etc. The signal acquisition unit 51 acquires detection signals from the encoder 13, the output shaft sensor 16, the current detection unit 45, the voltage detection circuit 46, and the like. The abnormality determination unit 52 determines abnormality in the shift-by-wire system 1. Details of the abnormality determination will be described below. The drive control unit 55 controls the on-off operation of the switching elements 411 to 413 to control the driving of the motor 10.

The following mainly describes abnormality detection with a case where a faulted phase is the U-phase as an example. The voltage detection circuit 46 includes voltage divider resistors (not illustrated) for each phase. The abnormality determination unit 52 identifies a faulted phase based on the voltage level at an intermediate connection between the voltage divider resistors in the voltage detection circuit 46. Hereinafter, the voltage level at the intermediate connection of the voltage divider resistors is referred to as a “port level”.

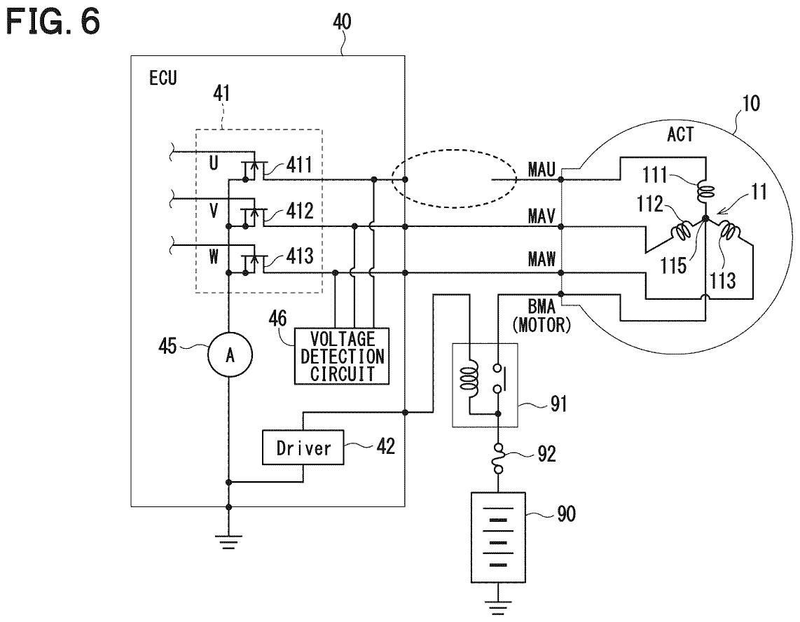

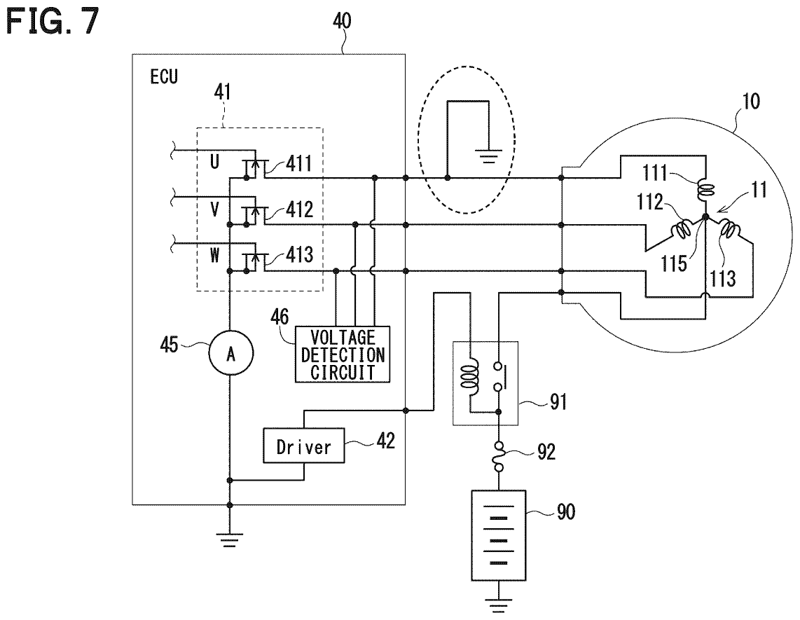

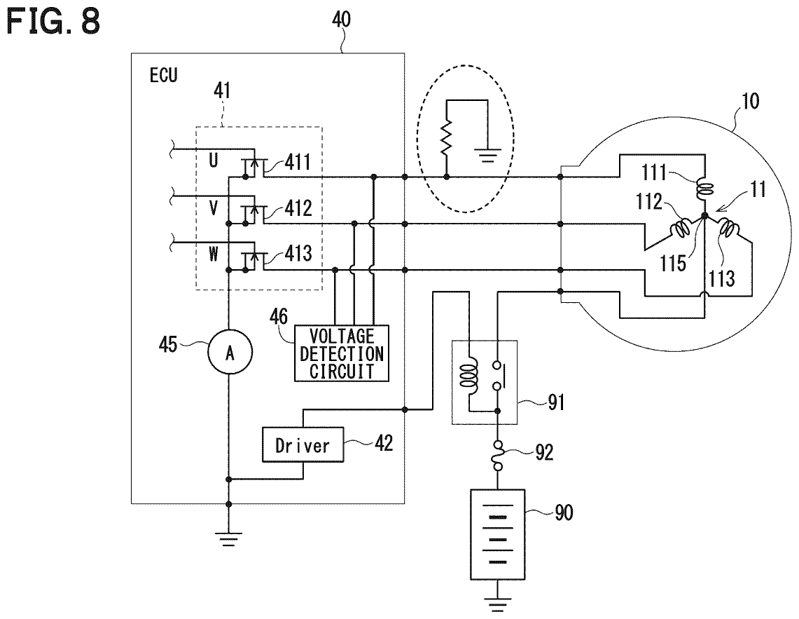

When the coils 111 to 113 are normal, the motor relay 91 is on, and the switching elements 411 to 413 are off, the port levels are a voltage level that depends on the battery voltage and the resistance value of the voltage divider resistors (hereinafter, a “high level”). On the other hand, when a break occurs in the U-phase energization line as indicated by a dashed ellipse in FIG. 6, the U-phase port level becomes a low level. When a short to ground occurs in the U-phase energization line as illustrated in FIGS. 7 and 8, the U-phase port level also becomes the low level.

In the present embodiment, a state in which an energization line is electrically connected to ground with resistance ≈0 as illustrated in FIG. 7 is referred to as a (complete) short to ground, and a state in which an energization line is electrically connected to ground with resistance as illustrated in FIG. 8 as an incomplete short to ground. In FIGS. 7 and 8 and FIGS. 9 and 10 described below, the state of the short to ground is schematically illustrated as a circuit enclosed by a dashed ellipse.

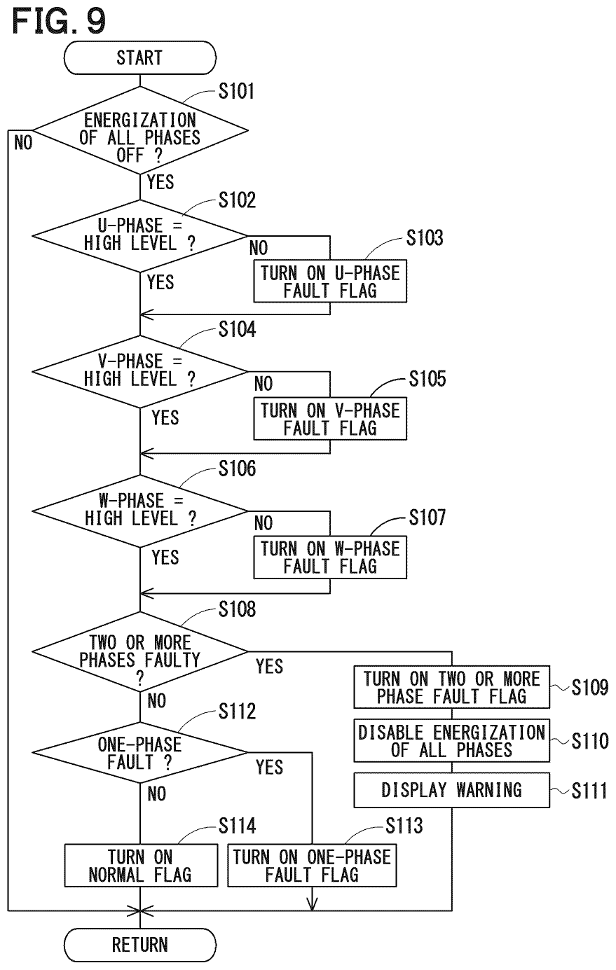

A faulted phase determination process based on the port levels will be described with reference to a flowchart of FIG. 9. This process is a process performed by the control unit 50 at predetermined periods (e.g. every 8 [ms]). Hereinafter, “step” of step S101 and the like is omitted and is simply denoted by the symbol “S”.

In S101, the control unit 50 determines whether the energization of all the phases has been turned off. When it is determined that the energization of all the phases has not been turned off (S101: NO), processing in and after S102 is skipped. When it is determined that the energization of all the phases has been turned off (S101: YES), the process proceeds to S102.

In S102, the abnormality determination unit 52 determines whether the U-phase port level is the high level. Here, when the U-phase port level is greater than or equal to a determination threshold set according to the battery voltage and the resistance value of the voltage divider resistors, it is determined that the U-phase port level is the high level, and when the U-phase port level is less than the determination threshold, it is determined that the U-phase port level is the low level. When it is determined that the U-phase port level is the low level (S102: NO), the process proceeds to S103, and a U-phase fault flag is turned on. When it is determined that the U-phase port level is the high level (S102: YES), the process proceeds to S104.

In S104, the abnormality determination unit 52 determines whether the V-phase port level is the high level. When it is determined that the V-phase port level is the low level (S104: NO), the process proceeds to S105, and a V-phase fault flag is turned on. When it is determined that the V-phase port level is the high level (S104: YES), the process proceeds to S106.

In S106, the abnormality determination unit 52 determines whether the W-phase port level is the high level. When it is determined that the W-phase port level is the low level (S106: NO), the process proceeds to S107, and a W-phase fault flag is turned on. When it is determined that the W-phase port level is the high level (S106: YES), the process proceeds to S108.

In S108, the abnormality determination unit 52 determines whether two or more phases are faulty. When it is determined that the number of faulted phases is one or less (S108: NO), the process proceeds to S112. When it is determined that two or more phases are faulty (S108: YES), the process proceeds to S109.

In S109, the abnormality determination unit 52 turns on a two or more phase fault flag. The control unit 50 disables the energization of all the phases in S110, and displays a warning on an instrument panel (not illustrated) in S111. Note that the warning may be displayed in any way. A voice warning or the like may be used.

In S112, the abnormality determination unit 52 determines whether there is a one-phase fault. When it is determined that there is a one-phase fault (S112: YES), the process proceeds to S113, and a one-phase fault flag is turned on. When it is determined that there is no one-phase fault (S112: NO), that is, when all the phases are normal, the process proceeds to S114, and a normal flag is turned on.

In the process of FIG. 9, a faulted phase(s) can be identified, but it is impossible to determine whether a fault occurring is a wire break fault or a permanent energization fault due to a short to ground. Here, if a fault occurring is a one-phase wire break, range switching can be performed using two normal phases.

On the other hand, when a fault occurring is a permanent energization fault due to a short to ground or the like, range switching with two normal phases cannot be performed. In addition, if the motor relay 91 remains on, current continues to flow through the faulted phase, and the motor 10 can overheat. Therefore, at the time of a permanent energization fault, it is desirable to turn off the motor relay 91 to stop the drive control of the motor 10.

For example, as a reference example, after a faulted phase is identified on the basis of the port levels, range switching is performed using two normal phases with open-loop drive in which energized phases are switched at predetermined time intervals. Based on whether the range switching was possible, it can be determined whether the fault is a wire break or a short to ground. However, with this method, there is concern about a delay in the determination. In the case of an incomplete short to ground in which a small amount of current flows toward ground as illustrated in FIG. 8, range switching is possible. If the fault is erroneously determined to be a wire break and the motor drive control is continued, the motor 10 can overheat.

Therefore, in the present embodiment, after a faulted phase is identified based on the port levels, it is determined whether the fault is a wire break fault or a short to ground fault, based on behavior when the switching elements 411 to 413 are turned on and off.

First, a description is given of a value detected by the current detection unit 45 when the switching element 411 of the U-phase, which is a faulted phase, is turned on. Even when the switching element 411 is turned on at the time of a U-phase wire break, no current flows through the U-phase energization line, and thus no current is detected by the current detection unit 45 (see FIG. 6).

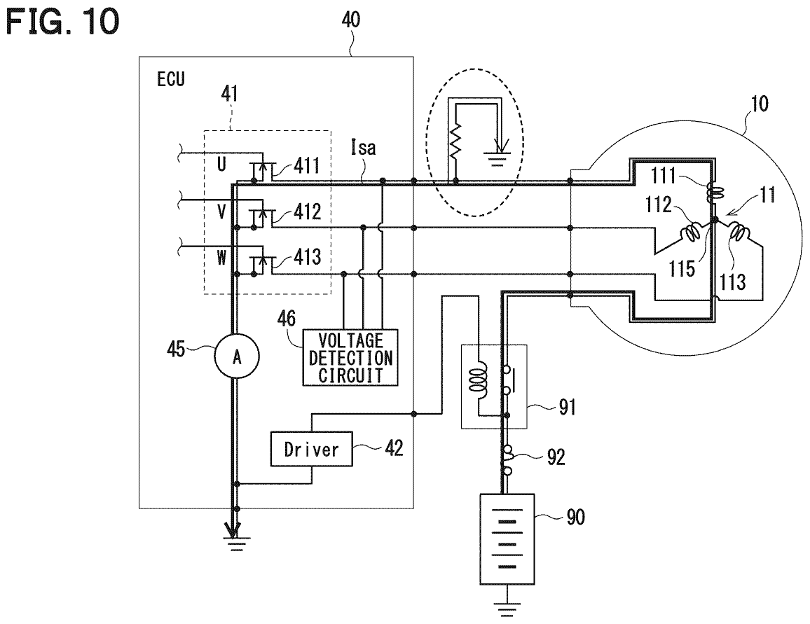

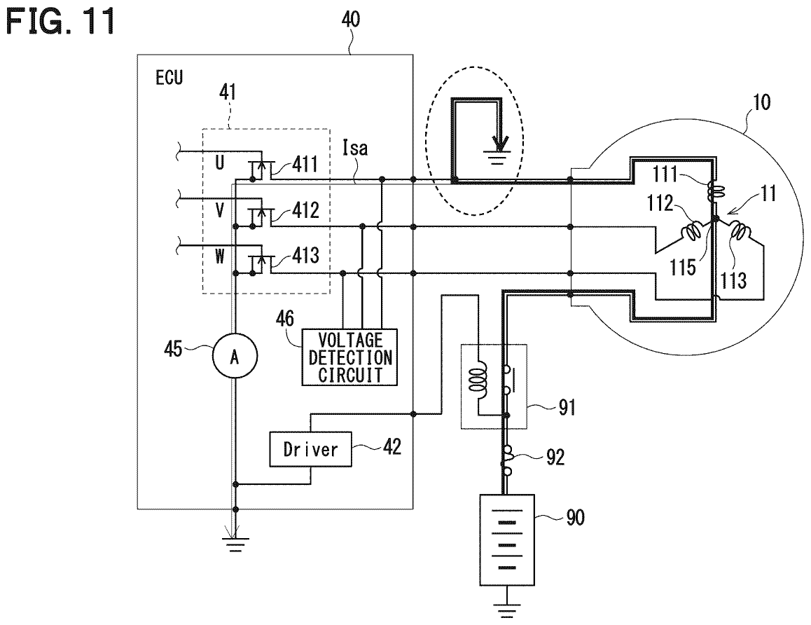

As indicated by an arrow Isa in FIGS. 10 and 11, when the switching element 411 is turned on at the time of a short to ground, current flows through the switching element 411. If the short to ground is incomplete and the resistance value of the short is relatively large, a relatively large current flows toward the current detection unit 45 (see FIG. 10). Therefore, at the time of a U-phase fault, it can be determined whether the fault is a wire break or an incomplete short to ground, based on the value detected by the current detection unit 45 when the switching element 411 is turned on.

As illustrated in FIG. 11, when the resistance of the short to ground approaches zero, the current flowing toward the current detection unit 45 becomes very small. Therefore, if the resistance of the short to ground is close to zero, it is difficult to determine whether the fault is a wire break or a short to ground, based on the value detected by the current detection unit 45 when the switching element 411 is turned on. In FIGS. 10 and 11, the amounts of current are schematically indicated by the thicknesses of arrows.

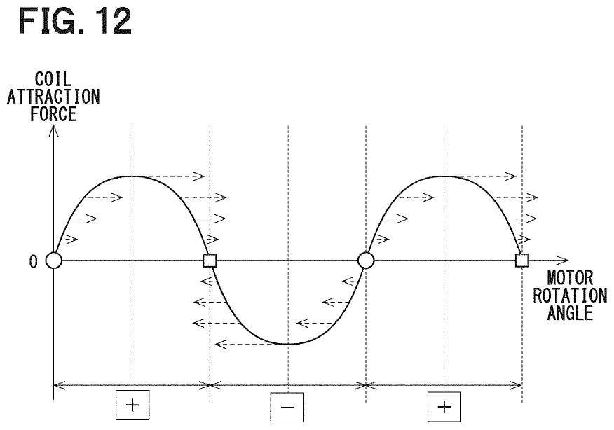

Therefore, in the present embodiment, abnormality determination is performed based on the motor rotation angle when energization of normal phases is performed in addition to the current value when the switching element of a faulted phase is turned on. Prior to the description of abnormality determination using the motor rotation angle, the behavior of the rotor 103 during energization will be described. FIG. 12 illustrates coil attraction force when the V-phase is energized, where the horizontal axis represents the motor rotation angle and the vertical axis represents the coil attraction force. In FIG. 12, at the positions of circles, the V-phase salient poles 102 of the stator 101 face the recesses 105 of the rotor 103, and at the positions of squares, the V-phase salient poles 102 face the projections 104 of the rotor 103.

When the switching element 412 is turned on to energize only the V-phase, the magnetic attraction force acts in directions in which the projections 104 move toward the V-phase salient poles 102, except when the recesses 105 face the V-phase salient poles 102 at the positions of the circles. In FIG. 12, the attraction force at the time of V-phase energization is schematically indicated by dashed arrows, and acts as a force to rotate the rotor 103 in the positive direction in regions indicated by “+”, and acts as a force to rotate the rotor 103 in the negative direction in a region indicated by “−”.

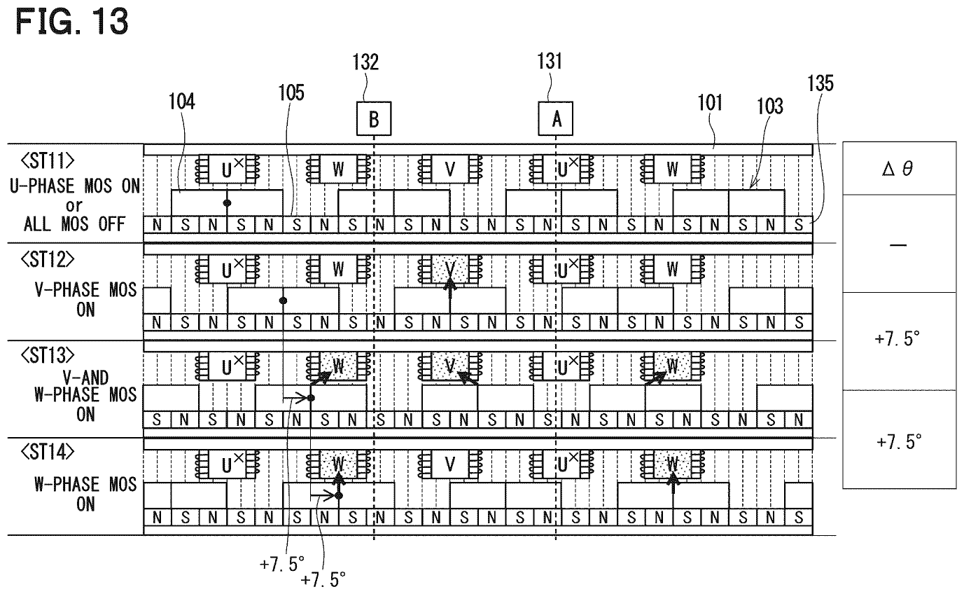

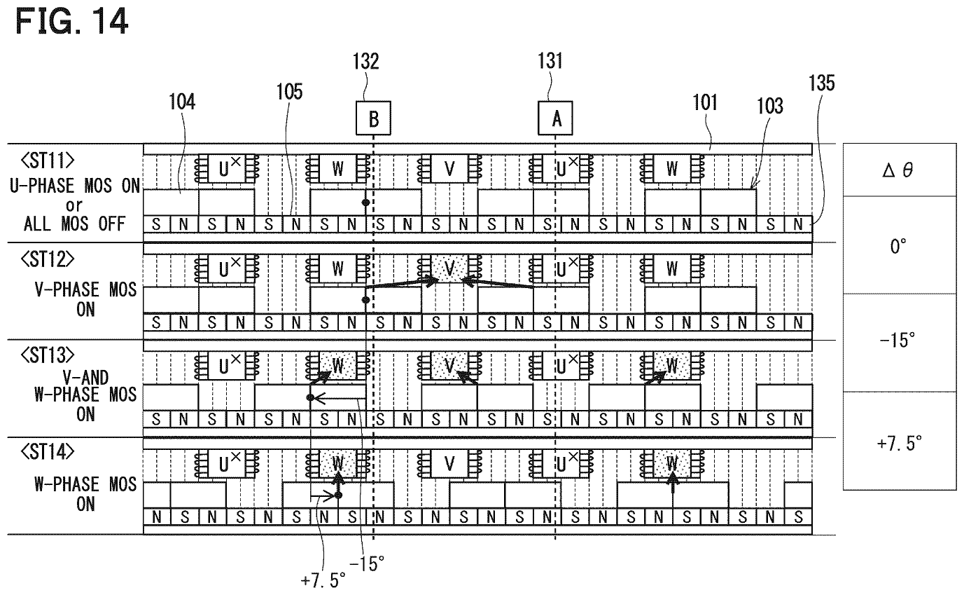

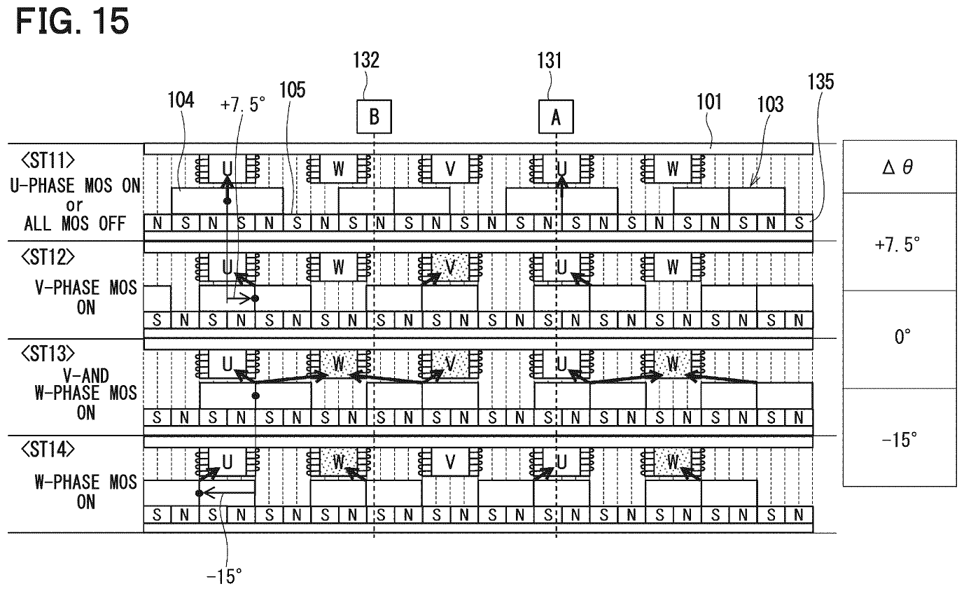

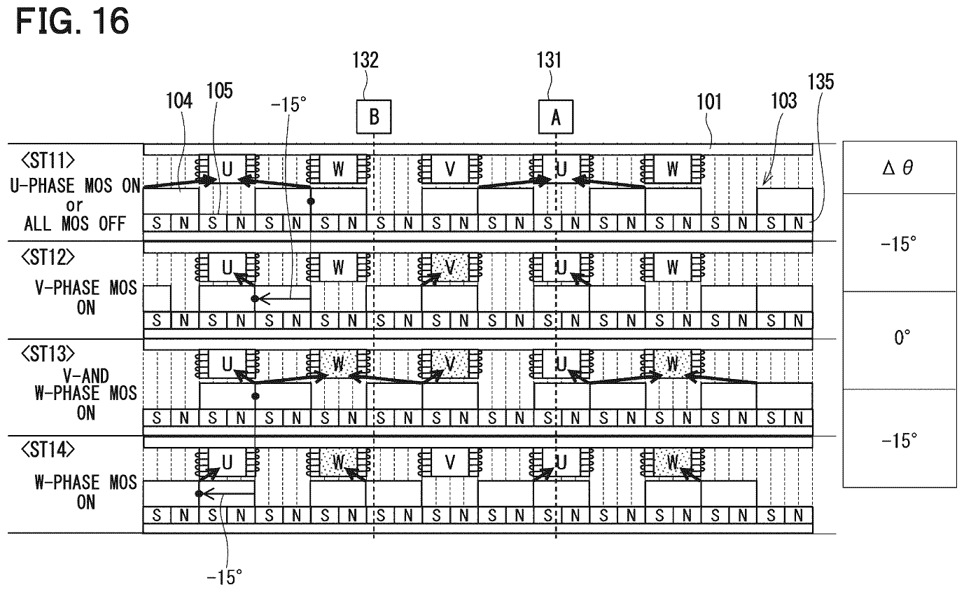

The behavior of the rotor 103 when energization patterns for the V-phase and the W-phase, which are normal phases, are switched at the time of a U-phase fault will be described with reference to FIGS. 13 to 16. FIGS. 13 and 14 illustrate the behavior at the time of a U-phase wire break, and FIGS. 15 and 16 illustrate the behavior at the time of a U-phase short to ground.

FIGS. 13 to 16 illustrate, from the top, an energization status ST11 in which the switching elements 411 to 413 of all the phases are turned off, an energization status ST12 in which the V-phase switching element 412 is turned on, an energization status ST13 in which the V-phase and W-phase switching elements 412 and 413 are turned on, and an energization status ST14 in which the W-phase switching element 413 is turned on. Energized phases are switched in this order in the description. When the U-phase switching element 411 is turned on at the time of a U-phase wire break, the behavior is similar to that when all the phases are off.

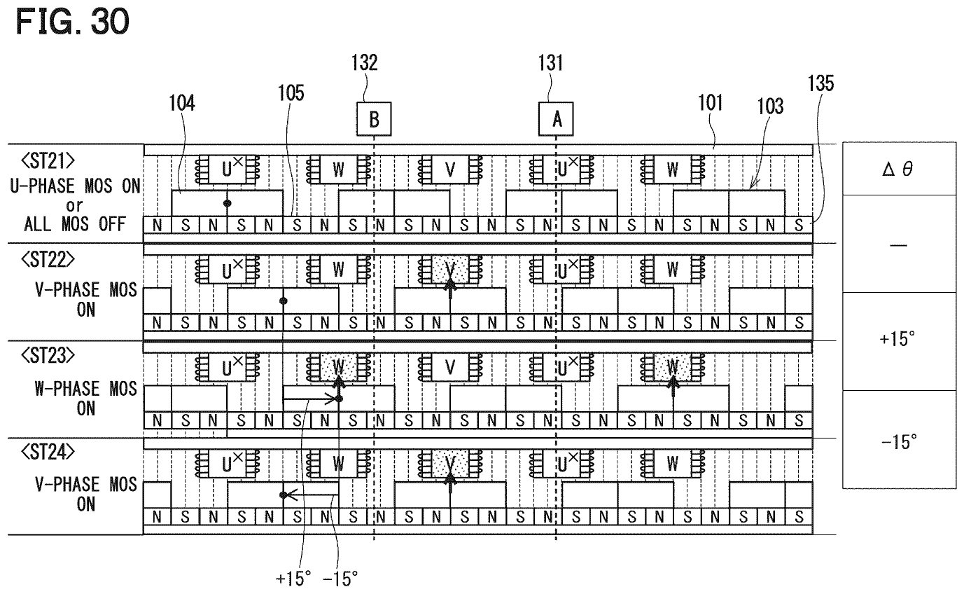

Left-side portions of FIGS. 13 to 16 are diagrams schematically illustrating the positional relationship between the salient poles 102 of the stator and the rotor 103 in an area enclosed by a dashed line L in FIG. 4 with rotational directions as left and right directions. The left direction is the positive rotational direction and the right direction is the negative rotational direction. In the diagrams on the left side, a phase not energized due to a wire break (the U-phase in examples of the U-phase wire break) is marked with x, and energized phases are indicated by dotted shading. On the right side, a rotation angle difference Δθ that is a difference in motor rotation angle when the energized phases are switched is illustrated. The same applies to FIG. 30 and the like.

FIG. 13 illustrates a case where the recesses 105 of the rotor 103 do not face the V-phase when all the phases are off at the time of a U-phase wire break. In the energization status ST11 in which all the phases are off, no attraction force of the motor windings 11 is generated, and thus the position of the rotor 103 is uncertain. At the time of the U-phase wire break, if the U-phase switching element 411 is turned on, the motor windings 11 are not energized, thus resulting in the same state.

When the energization status proceeds from ST11 to ST12 to turn on the V-phase switching element 412 to energize the V-phase, the coils 112 are energized, generating attraction force. Consequently, the projections 104 of the rotor 103 rotate to positions to face the V-phase. Since the rotor position is uncertain in the energization status ST11, the rotation angle difference Δθ when the energization status proceeds from ST11 to ST12 is a value that depends on the rotor position in the energization status ST11.

When the energization status proceeds from ST12 to ST13 to turn on the V-phase and W-phase switching elements 412 and 413 to energize the V-phase and W-phases, the coils 112 and 113 are energized, and the projections 104 rotate +7.5° to positions to face the V-phase and the W-phase. That is, the rotation angle difference Δθ when the energization status proceeds from ST12 to ST13 is +7.5°.

When the energization status proceeds from ST13 to ST14 to turn off the V-phase switching element 412 and turn on the W-phase switching element 413 to energize the W-phase, the coils 113 are energized, and the projections 104 rotate +7.5° to positions to face the W-phase. That is, the rotation angle difference Δθ when the energization status proceeds from ST13 to ST14 is +7.5°.

FIG. 14 illustrates a case where the recesses 105 of the rotor 103 face the V-phase when all the phases are off at the time of a U-phase wire break. When the energization status proceeds from ST11 to ST12 to turn on the V-phase switching element 412 to energize the V-phase, the coils 112 are energized. When the recesses 105 face the V-phase in the energization status ST11, the left and right projections 104 are attracted to the V-phase, so that the recesses 105 remain facing the V-phase, and the rotor 103 does not rotate. That is, the rotation angle difference Δθ when the energization status proceeds from ST11 to ST12 is 0°.

When the energization status proceeds from ST12 to ST13 to turn on the V-phase and W-phase switching elements 412 and 413, the coils 112 and 113 are energized, and the projections 104 rotate −15° to positions to face the V-phase and the W-phase. That is, the rotation angle difference Δθ when the energization status proceeds from ST12 to ST13 is −15°.

When the energization status proceeds from ST13 to ST14 to turn off the V-phase switching element 412 and turn on the W-phase switching element 413, the coils 113 are energized, and the projections 104 rotate +7.5° to positions to face the W-phase. That is, as in FIG. 13, the rotation angle difference Δθ when the energization status proceeds from ST13 to ST14 is +7.5°.

FIG. 15 illustrates a case where in the energization status ST11, the U-phase coils 111 are energized due to a U-phase short to ground, and the projections 104 face the U-phase. When the energization status proceeds from ST11 to ST12 to turn on the V-phase switching element 412, the U-phase and V-phases are energized, and the projections 104 rotate +7.5° to positions to face the U-phase and the V-phase. That is, the rotation angle difference Δθ when the energization status proceeds from ST11 to ST12 is +7.5°.

When the energization status proceeds from ST12 to ST13 to turn on the V-phase and W-phase switching elements 412 and 413, W-phase energization is added, but the rotor 103 does not rotate because the W-phase faces the recesses 105. That is, the rotation angle difference Δθ when the energization status proceeds from ST12 to ST13 is 0°.

When the energization status proceeds from ST13 to ST14 to turn off the V-phase switching element 412 and turn on the W-phase switching element 413, the W-phase and U-phases are energized, and the projections 104 rotate −15° to positions to face the U-phase and the W-phase. That is, the rotation angle difference Δθ when the energization status proceeds from ST13 to ST14 is −15°.

FIG. 16 illustrates a case where in the energization status ST11, the U-phase coils 111 are energized due to a U-phase short to ground, and the recesses 105 face the U-phase. When the energization status proceeds from ST11 to ST12 to turn on the V-phase switching element 412, the U-phase and V-phases are energized, and the projections 104 rotate −15° to positions to face the U-phase and the V-phase. That is, the rotation angle difference Δθ when the energization status proceeds from ST11 to ST12 is −15°.

When the energization status proceeds from ST12 to ST13 to turn on the V-phase and W-phase switching elements 412 and 413, W-phase energization is added, but the rotor 103 does not rotate because the W-phase faces the recesses 105. That is, the rotation angle difference Δθ when the energization status proceeds from ST12 to ST13 is 0°.

When the energization status proceeds from ST13 to ST14 to turn off the V-phase switching element 412 and turn on the W-phase switching element 413, the W-phase and U-phases are energized, and the projections 104 rotate −15° to positions to face the U-phase and the W-phase. That is, as in FIG. 15, the rotation angle difference Δθ when the energization status proceeds from ST13 to ST14 is −15°.

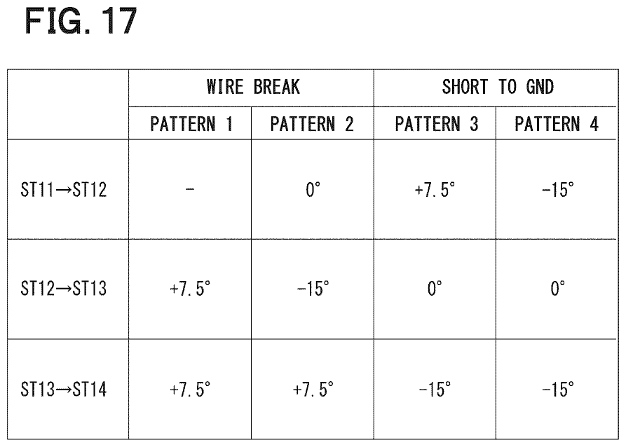

FIG. 17 is a diagram for explaining the rotation angle difference Δθ in response to the switching between the energization statuses ST11 to ST14. Pattern 1 in FIG. 17 corresponds to FIG. 13 and is a pattern in which in the energization status ST11, the recesses 105 do not face the phase to be energized in the energization status ST12. Pattern 2 corresponds to FIG. 14 and is a pattern in which in the energization status ST11, the recesses 105 face the phase to be energized in the energization status ST12. Pattern 3 corresponds to FIG. 15 and is a pattern in which in the energization status ST11, the projections 104 face the phase with a permanent energization fault. Pattern 4 corresponds to FIG. 16 and is a pattern in which in the energization status ST11, the recesses 105 face the phase with a permanent energization fault.

As illustrated in FIG. 17, in the case where the energized phases are switched from the energization status ST11 to ST14, at the time of proceeding from the energization status ST13 to ST14, the rotational direction of the rotor 103 when a U-phase wire break has occurred is different from that when a short to ground has occurred, regardless of the rotor position in the energization status ST11. Therefore, it is possible to determine whether the fault is a wire break or a short to ground. In particular, at the time of a short to ground with small resistance that is difficult to determine based on the current value when a faulted phase is on, an energized state when the switching element of one normal phase is turned on is closer to a state with two-phase energization, and encoder outputs are likely to stabilize under conditions similar to those at the time of two-phase energization and thus facilitate the determination.

When the energization status is switched from ST13 to ST14 while all the phases are normal, the behavior is similar to that at the time of a wire break. Therefore, the rotor rotational direction at the time of a short to ground when the energization status is switched from ST13 to ST14 can also be considered to be different from the rotational direction when all the phases are normal.

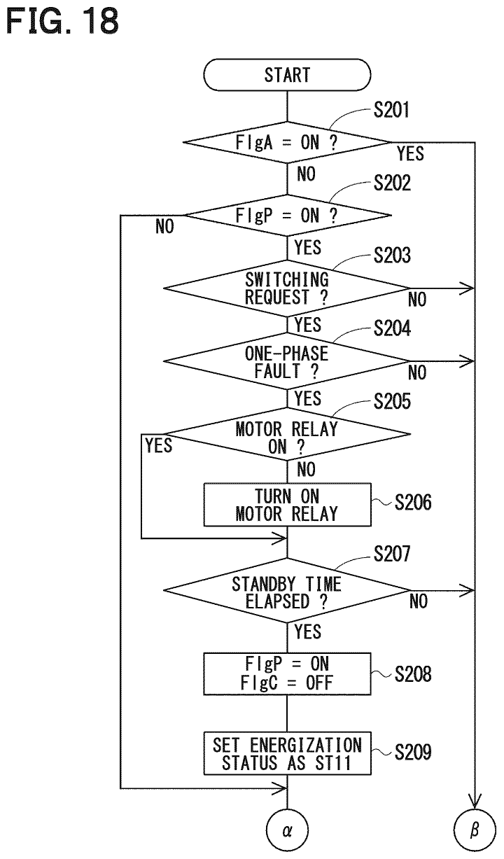

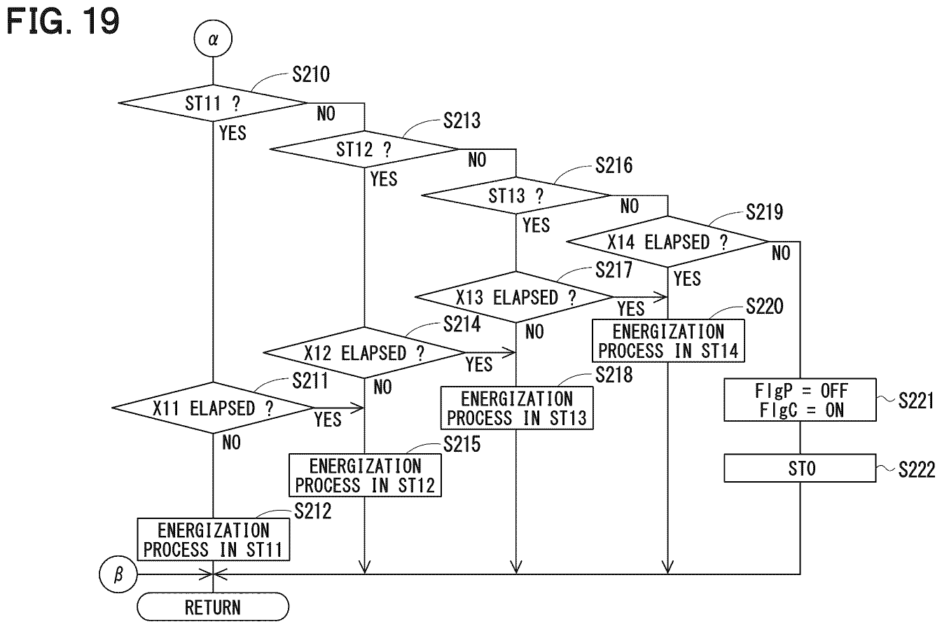

An energization process related to fault identification will be described with reference to flowcharts of FIGS. 18 and 19. In S201, the control unit 50 determines whether a permanent energization fault flag FlgA to be described below has been turned on. When it is determined that the permanent energization fault flag FlgA has been turned on (S201: YES), processing in and after S202 is skipped. When it is determined that the permanent energization fault flag FlgA is off (S201: NO), the process proceeds to S202.

In S202, the control unit 50 determines whether a pre-two-phase-switching energization process flag FlgP has been turned on. When it is determined that the pre-two-phase-switching energization process flag FlgP has been turned on (S202: YES), the process proceeds to S210. When it is determined that the pre-two-phase-switching energization process flag is off (S202: NO), the process proceeds to S203.

In S203, the control unit 50 determines whether there is a shift range switching request. When it is determined that there is no shift range switching request (S203: NO), processing in and after S204 is skipped. When it is determined that there is a shift range switching request (S203: YES), the process proceeds to S204.

In S204, the control unit 50 determines whether the one-phase fault flag has been turned on. A one-phase fault is determined in the faulted phase determination process in FIG. 9. When it is determined that the one-phase fault flag is off (S204: NO), processing in and after S205 is skipped. When it is determined that the one-phase fault flag has been turned on (S204: YES), the process proceeds to S205.

In S205, the control unit 50 determines whether the motor relay 91 has been turned on. When it is determined that the motor relay 91 has not been turned on (S205: NO), the process proceeds to S206 to turn on the motor relay 91. When it is determined that the motor relay 91 has been turned on (S205: YES), the process proceeds to S207.

In S207, the control unit 50 determines whether a standby time after turning on the motor relay 91 has elapsed with an ON delay of the motor relay 91 taken into consideration. When it is determined that the standby time after turning on the motor relay 91 has not elapsed (S207: NO), processing in and after S208 is skipped. When it is determined that the standby time after turning on the motor relay 91 has elapsed (S207: YES), the process proceeds to S208.

In S208, the control unit 50 turns on the pre-two-phase-switching energization process flag FlgP and turns off a pre-two-phase-switching energization completion flag FlgC. In S209, the control unit 50 sets the status as the energization status ST11.

As illustrated in FIG. 19, in S210, the control unit 50 determines whether the current status is the energization status ST11. When it is determined that the current status is not the energization status ST11 (S210: NO), the process proceeds to S213. When it is determined that the current status is the energization status ST11 (S210: YES), the process proceeds to S211.

In S211, the control unit 50 determines whether a duration X11 has elapsed since the start of the energization status ST11. When it is determined that the duration X11 has elapsed (S211: YES), the status is set as the energization status ST12, and the process proceeds to S215. When it is determined that the duration X11 has not elapsed (S211: NO), the process proceeds to S212.

In S212, the control unit 50 performs energization in the energization status ST11. The energization status ST11 is faulted-phase energization. When the U-phase fault flag has been turned on, the U-phase switching element 411 is turned on. When the V-phase fault flag has been turned on, the V-phase switching element 412 is turned on. When the W-phase fault flag has been turned on, the W-phase switching element 413 is turned on.

In S213 to which the process proceeds when it is determined that the current status is not the energization status ST11 (S210: NO), the control unit 50 determines whether the current status is the energization status ST12. When it is determined that the current status is not the energization status ST12 (S213: NO), the process proceeds to S216. When it is determined that the current status is the energization status ST12 (S213: YES), the process proceeds to S214.

In S214, the control unit 50 determines whether a duration X12 has elapsed since the start of the energization status ST12. When it is determined that the duration X12 has elapsed (S214: YES), the status is set as the energization status ST13, and the process proceeds to S218. When it is determined that the duration X12 has not elapsed (S214: NO), the process proceeds to S215.

In S215, the control unit 50 performs energization in the energization status ST12. The energization status ST12 is one-normal-phase energization. When the U-phase fault flag has been turned on, the V-phase switching element 412 is turned on. When the V-phase fault flag has been turned on, the W-phase switching element 413 is turned on. When the W-phase fault flag has been turned on, the U-phase switching element 411 is turned on.

In S216 to which the process proceeds when it is determined that the current status is not the energization status ST12 (S213: NO), the control unit 50 determines whether the current status is the energization status ST13. When it is determined that the current status is not the energization status ST13 (S216: NO), the process proceeds to S219. When it is determined that the current status is the energization status ST13 (S216: YES), the process proceeds to S217.

In S217, the control unit 50 determines whether a duration X13 has elapsed since the start of the energization status ST13. When it is determined that the duration X13 has elapsed (S217: YES), the status is set as the energization status ST14, and the process proceeds to S220. When it is determined that the duration X13 has not elapsed (S217: NO), the process proceeds to S218.

In S218, the control unit 50 performs energization in the energization status ST13. The energization status ST13 is two-normal-phase energization. When the U-phase fault flag has been turned on, the V-phase and W-phase switching elements 412 and 413 are turned on. When the V-phase fault flag has been turned on, the U-phase and W-phase switching elements 411 and 413 are turned on. When the W-phase fault flag has been turned on, the U-phase and V-phase switching elements 411 and 412 are turned on.

In S219 to which the process proceeds when it is determined that the current status is not the energization status ST13 (S216: NO), the control unit 50 determines whether a duration X14 has elapsed since the start of the energization status ST14. The durations X11 to X14 can be set as desired. At least some of the durations X11 to X14 may be the same or different. When it is determined that the duration X14 has not elapsed (S219: NO), the process proceeds to S221. When it is determined that the duration X14 has elapsed (S219: YES), the process proceeds to S220.

In S220, the control unit 50 performs energization in the energization status ST14. The energization status ST14 is one-phase energization of a normal phase different from that in the energization status ST12. When the U-phase fault flag has been turned on, the W-phase switching element 413 is turned on. When the V-phase fault flag has been turned on, the U-phase switching element 411 is turned on. When the W-phase fault flag has been turned on, the V-phase switching element 412 is turned on.

In S221 to which the process proceeds after the elapse of the duration X14 since the start of the energization status ST14, the control unit 50 turns off the pre-two-phase-switching energization process flag FlgP and turns off the pre-two-phase-switching energization completion flag FlgC. In S222, the control unit 50 sets the energization status as undetermined ST0. Energized phases in the one-normal-phase energization in the energization statuses ST12 and ST14 can be set as desired. Based on the rotational direction that depends on the set energized phases, it can be determined whether the fault is a wire break or permanent energization.

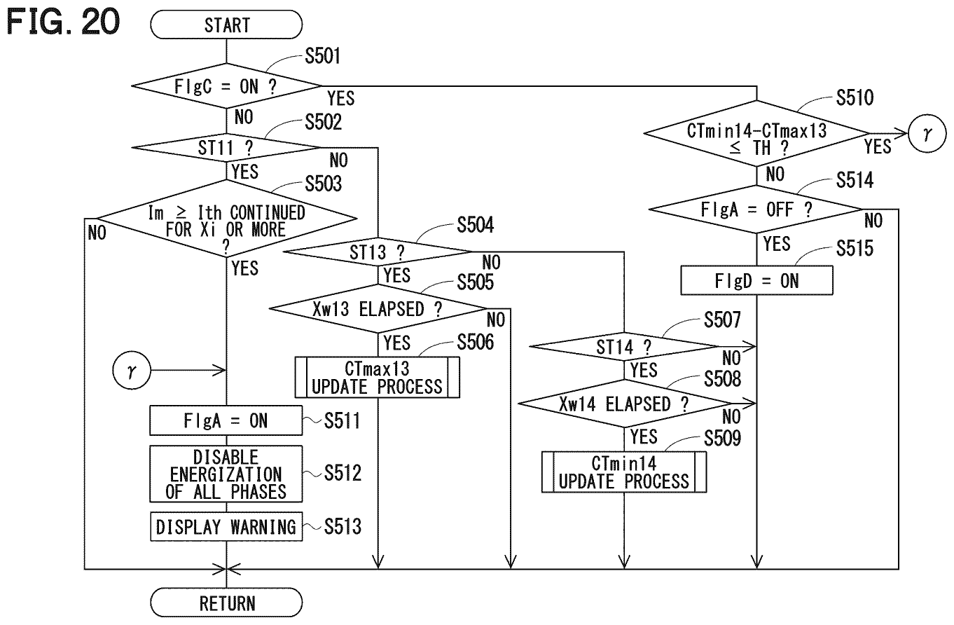

A fault condition determination process will be described with reference to a flowchart of FIG. 20. In S501, the abnormality determination unit 52 determines whether the pre-two-phase-switching energization completion flag FlgC has been turned on. When it is determined that the pre-two-phase-switching energization completion flag has been turned on (S501: YES), the process proceeds to S510. When it is determined that the pre-two-phase-switching energization completion flag FlgC is off (S501: NO), the process proceeds to S502.

In S502, the abnormality determination unit 52 determines whether the current status is the energization status ST11. When it is determined that the current status is not the energization status ST11 (S502: NO), the process proceeds to S504. When it is determined that the current status is the energization status ST11 (S502: YES), the process proceeds to S503.

In S503, the abnormality determination unit 52 determines whether the motor current Im has continued to be greater than or equal to a current determination threshold Ith for a determination time Xi or more. The current determination threshold Ith is set according to current flowing through the current detection unit 45 when a short to ground occurs. The determination time Xi is set to a time shorter than the duration X11. When it is determined that the motor current Im is less than the current determination threshold Ith or that the time for which the motor current Im has continued to be greater than or equal to the current determination threshold Ith is less than the determination time Xi (S503: NO), the subsequent processing is skipped. When it is determined that the motor current Im has continued to be greater than or equal to the current determination threshold Ith for the determination time Xi or more (S503: YES), the process proceeds to S511.

In S504, the abnormality determination unit 52 determines whether the current status is the energization status ST13. When it is determined that the current status is not the energization status ST13 (S504: NO), the process proceeds to S507. When it is determined that the current status is the energization status ST13 (S504: YES), the process proceeds to S505.

In S505, the abnormality determination unit 52 determines whether a standby time Xw13 has elapsed since the start of the energization status ST13. The standby time Xw13 is set according to the time for the vibration of the rotor 103 to subside to some extent in the energization status ST13. When it is determined that the standby time Xw13 has not elapsed since the start of the energization status ST13 (S505: NO), the subsequent processing is skipped. When it is determined that the standby time Xw13 has elapsed since the start of the energization status ST13 (S505: YES), the process proceeds to S506 to perform an update process on a maximum value CTmax13 in the energization status ST13. The update process on the maximum value CTmax13 will be described below.

In S507, the abnormality determination unit 52 determines whether the current status is the energization status ST14. When it is determined that the current status is not the energization status ST14 (S507: NO), the subsequent processing is skipped. When it is determined that the current status is the energization status ST14 (S507: YES), the process proceeds to S508.

In S508, the abnormality determination unit 52 determines whether a standby time Xw14 has elapsed since the start of the energization status ST14. The standby time Xw14 is set according to the time for the vibration of the rotor 103 to subside to some extent in the energization status ST14, and may be the same as or different from the standby time Xw13. The same applies to a standby time Xw12 and the like in the embodiments described below. When it is determined that the standby time Xw14 has not elapsed since the start of the energization status ST14 (S508: NO), the subsequent processing is skipped. When it is determined that the standby time Xw14 has elapsed since the start of the energization status ST14 (S508: YES), the process proceeds to S509 to perform an update process on a minimum value CTmin14 in the energization status ST14.

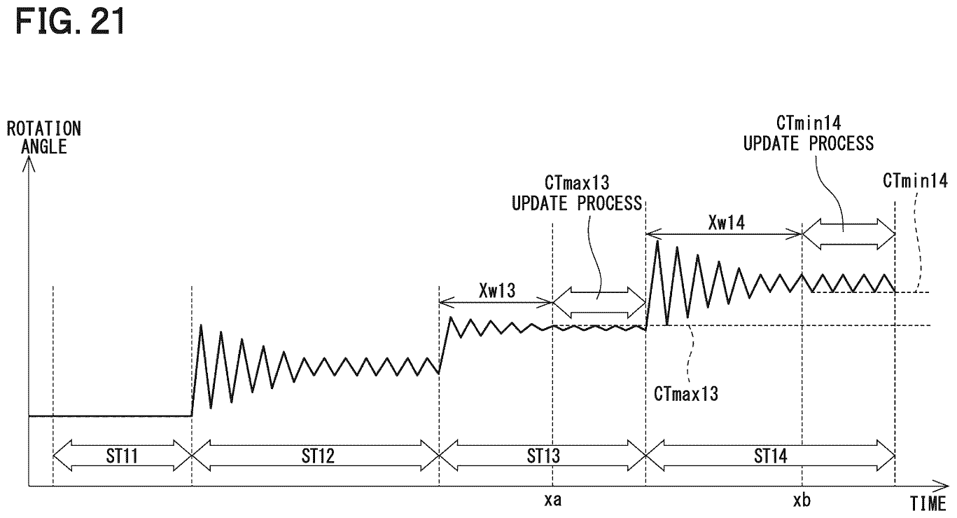

The update process on the maximum value CTmax13 in the energization status ST13 and the update process on the minimum value CTmin14 in the energization status ST14 will be described with reference to FIGS. 21 to 23. FIG. 21 is a diagram for explaining the behavior of the rotor 103 in the energization statuses ST11 to ST14, where the horizontal axis represents time and the vertical axis represents the motor rotation angle. Here, the behavior at the time of a U-phase wire break is illustrated as an example. In the present embodiment, the encoder 13 is used to detect the rotational position of the rotor 103, and the rotation angle is converted from the encoder count value. Hereinafter, the rotation angle is read as the encoder count value as appropriate.

The update process on the maximum value CTmax13 is performed from time xa at which the standby time Xw13 to wait for the vibration of the rotor 103 to decrease has elapsed since the start of the energization status ST13, until the energization status proceeds to ST14. The update process on the minimum value CTmin14 is performed from time xb at which the standby time Xw14 to wait for the vibration of the rotor 103 to decrease has elapsed since the start of the energization status ST14, until the energization status ST14 ends. The energization status ST14, which is one-phase energization, takes more time for the vibration of the rotor 103 to decrease than the energization status ST13, which is two-phase energization. Thus, the standby time Xw14 is set to be longer than the standby time Xw13.

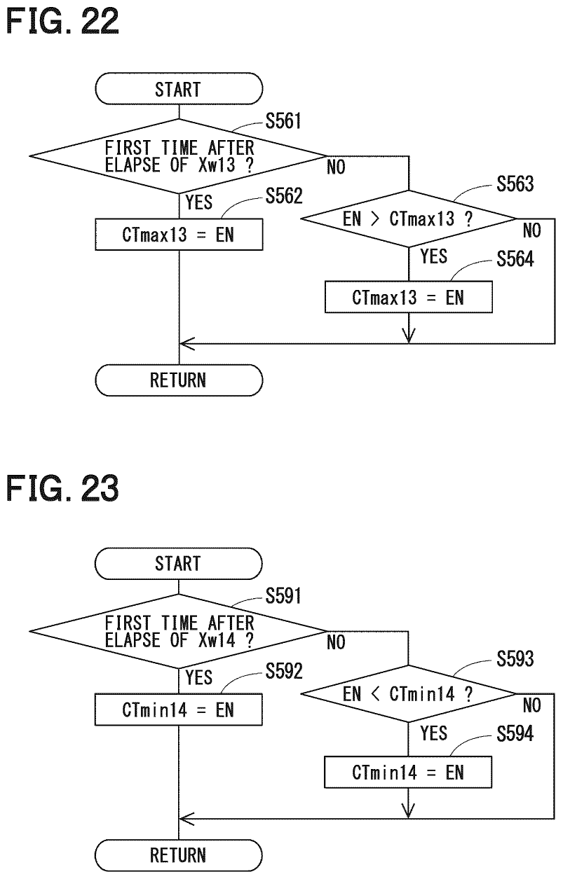

FIG. 22 illustrates a sub-flow of the update process on the maximum value CTmax13 in the energization status ST13 (S506 in FIG. 20). In S561, the abnormality determination unit 52 determines whether it is the first calculation after the elapse of the standby time Xw13. When it is determined that it is the first calculation after the elapse of the standby time Xw13 (S561: YES), the process proceeds to S562 to set the current encoder count value EN as the maximum value CTmax13. When it is determined that it is not the first calculation after the elapse of the standby time Xw13 (S561: NO), the process proceeds to S563.

In S563, the abnormality determination unit 52 determines whether the current encoder count value EN is greater than the maximum value CTmax13. When it is determined that the current encoder count value EN is less than or equal to the maximum value CTmax13 (S563: NO), a value held as the maximum value CTmax13 is not updated, and the present process is terminated. When it is determined that the current encoder count value EN is greater than the maximum value CTmax13 (S563: YES), the process proceeds to S564 to update the maximum value CTmax13 to the current encoder count value EN.

FIG. 23 illustrates a sub-flow of the update process on the minimum value CTmin14 in the energization status ST14 (S509 in FIG. 20). In S591, the abnormality determination unit 52 determines whether it is the first calculation after the elapse of the standby time Xw14. When it is determined that it is the first calculation after the elapse of the standby time Xw14 (S591: YES), the process proceeds to S592 to set the current encoder count value EN as the minimum value CTmin14. When it is determined that it is not the first calculation after the elapse of the standby time Xw14 (S591: NO), the process proceeds to S593.

In S593, the abnormality determination unit 52 determines whether the current encoder count value EN is less than the minimum value CTmin14. When it is determined that the current encoder count value EN is greater than or equal to the minimum value CTmin14 (S593: NO), a value held as the minimum value CTmin14 is not updated, and the present process is terminated. When it is determined that the current encoder count value EN is less than the minimum value CTmin14 (S593: YES), the process proceeds to S594 to update the minimum value CTmin14 to the current encoder count value EN.

Returning to FIG. 20, in S510 to which the process proceeds when it is determined that the pre-two-phase-switching energization completion flag FlgC is on (S501: YES), the abnormality determination unit 52 determines whether a value obtained by subtracting the maximum value CTmax13 in the energization status ST13 from the minimum value CTmin14 in the energization status ST14 is less than or equal to a determination threshold TH. The determination threshold TH can be set to any value that allows distinguishing between different rotational directions that depend on whether the fault is a one-phase wire break or a short to ground, and is set, for example, to zero or a value close to zero. When it is determined that the value obtained by subtracting the maximum value CTmax13 from the minimum value CTmin14 is less than or equal to the determination threshold TH (S510: YES), that is, when the rotational direction of the rotor 103 when the energization status proceeds from ST13 to ST14 is negative, the process proceeds to S511. When it is determined that the value obtained by subtracting the maximum value CTmax13 from the minimum value CTmin14 is greater than the determination threshold TH (S510: NO), the process proceeds to S514.

In S511 to which the process proceeds when it is determined that the motor current Im has continued to be greater than or equal to the current determination threshold Ith for the determination time Xi or more in the energization status ST11 (S503: YES), or when it is determined that the value obtained by subtracting the maximum value CTmax13 from the minimum value CTmin14 after pre-two-phase-switching energization process completion is less than or equal to the determination threshold TH (S510: YES), the abnormality determination unit 52 determines that a permanent energization fault due to a short to ground or the like has occurred and turns on the permanent energization fault flag FlgA. Processing in S512 and S513 is the same as the processing in S110 and S111 in FIG. 9, in which the energization of all the phases is disabled and the warning is displayed.

In S514 to which the process proceeds when it is determined that the value obtained by subtracting the maximum value CTmax13 from the minimum value CTmin14 is greater than the determination threshold TH (S510: NO), the abnormality determination unit 52 determines whether the permanent energization fault flag FlgA is off. When it is determined that the permanent energization fault flag FlgA is on (S514: NO), processing in S515 is skipped. When it is determined that the permanent energization fault flag FlgA is off (S515: YES), the process proceeds to S515 to turn on a one-phase wire break fault flag FlgD.

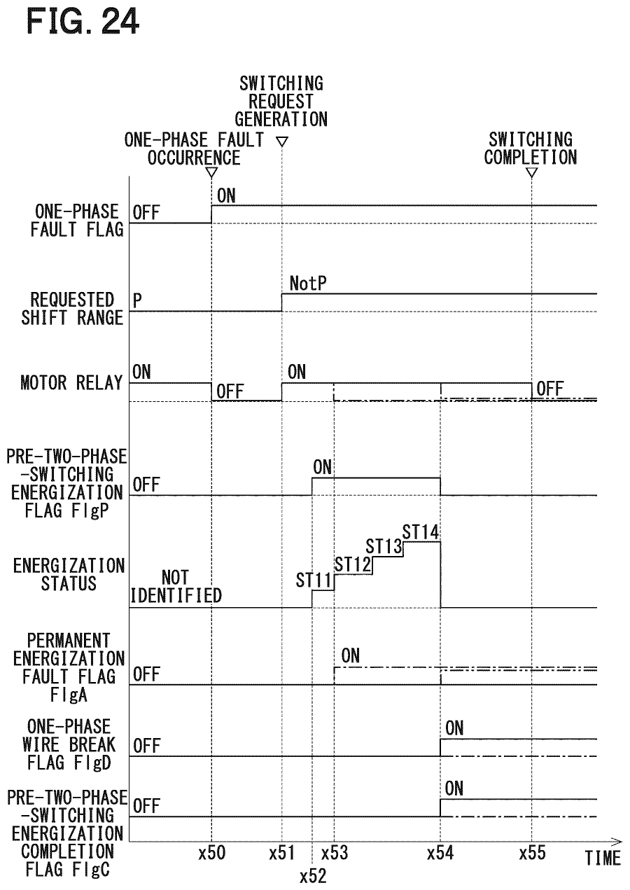

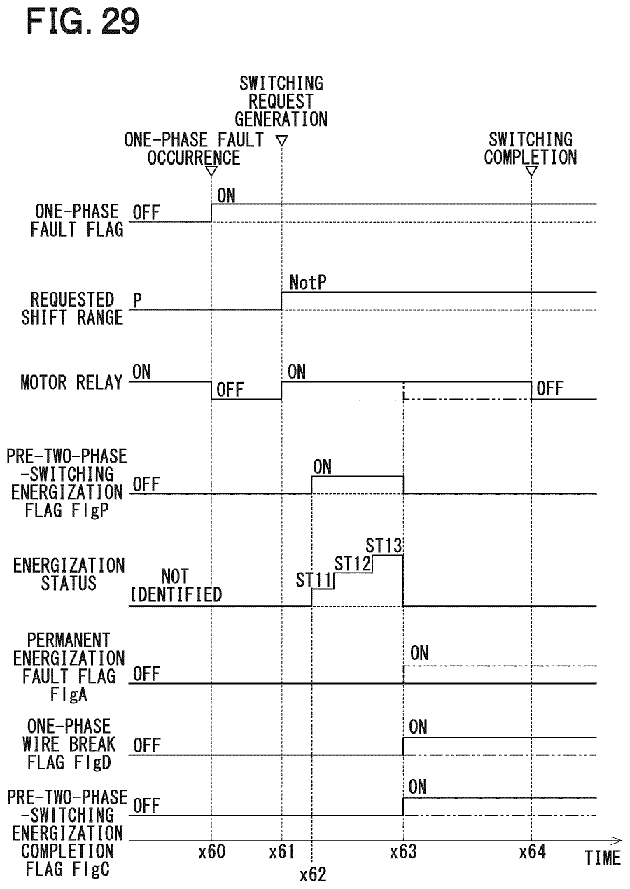

A range switching process in the present embodiment will be described with reference to a time chart of FIG. 24. FIG. 24 illustrates, from the top, the one-phase fault flag, the requested shift range, the on-off state of the motor relay 91, the pre-two-phase-switching energization process flag FlgP, the energization status, the permanent energization fault flag FlgA, the one-phase wire break flag FlgD, and the pre-two-phase-switching energization completion flag FlgC, with the horizontal axis as a common time axis. The same applies to FIG. 29 in an embodiment described below.

When a one-phase fault occurs and the one-phase fault flag is turned on in the faulted phase determination process at time x50, the motor relay 91 is turned off. When a range switching request is generated at time x51, the requested shift range is changed from the P range to the notP range, and the motor relay 91 is turned on.

When the pre-two-phase-switching energization process flag FlgP is turned on at time x52, the energization status is set as ST11, and the faulted phase is energized. When the fault is identified as a permanent energization fault based on the motor current Im at time x53, the permanent energization fault flag FlgA is turned on and the motor relay 91 is turned off as indicated by dash-dotted lines. When the fault is identified as a permanent energization fault due to a short to ground in the energization status ST11, the processing in and after the energization status ST12 and range switching using two normal phases are not performed.

When a permanent energization fault is not identified in the energization status ST11, energization is sequentially performed in the energization statuses ST12, ST13, and ST14. For the sake of simplicity, FIG. 24 illustrates the timing at which the permanent energization fault flag FlgA is turned on in alignment with the timing at which the energization status is switched from ST11 to ST12. However, in actuality, the proceeding to the energization status ST12 is set to be later.

When the energization status ST14 ends at time x54, the pre-two-phase-switching energization completion flag FlgC is turned on. Here, when the fault is identified as a permanent energization fault, based on the maximum value CTmax13 in the energization status ST13 and the minimum value CTmin14 in the energization status ST14, the permanent energization fault flag FlgA is turned on and the motor relay 91 is turned off as indicated by two-dot chain lines. When the fault is not identified as a permanent energization fault, based on the maximum value CTmax13 and the minimum value CTmin14, the fault is identified as a one-phase wire break, and the one-phase wire break flag FlgD is turned on as indicated by a solid line.

When the fault occurring in the faulted phase is identified as a one-phase wire break, not a permanent energization due to a short to ground, range switching is performed with feedback control based on the encoder count value, using two normal phases.

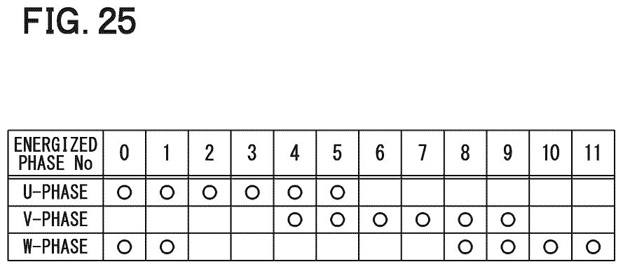

In shift range switching drive, the motor 10 is driven by switching energized phases of the motor windings 11 with feedback control based on the encoder count value. Specifically, as illustrated in FIG. 25, the control unit 50 has a map in which energized phase numbers are associated with energized phases. Each time a pulse edge of an encoder signal is detected, the control unit 50 shifts the energized phase number by one to switch the energized phases to rotate the motor 10. When the motor 10 is rotated in the forward direction, the energized phase number is incremented by one each time a pulse edge of the encoder signal is detected. When the motor 10 is rotated in the reverse direction, the energized phase number is decremented by one. The energized phase number can also be considered as a remainder when the encoder count value is divided by twelve, for example.

If a stagnation abnormality in which the encoder count value stagnates occurs during normal operation, the motor 10 is rotated with open-loop drive in which energized phases are switched at predetermined time intervals. In open-loop drive, an excitation time for each energized phase is set to a relatively long time (e.g. 50 [ms]) in order to reliably hold the projections 104 of the rotor 103 with the energized phase to synchronize the rotation phase of the rotor 103 and the energization phase.

In the case of a one-phase wire break, the motor 10 is driven by the energization of two normal phases with feedback control, to perform range switching. For example, in the case of a U-phase wire break, the W-phase is energized when the energized phase number is “0” or “1”, and the V-phase is energized when the energized phase number is “4” or “5”. Although no torque is produced in regions of the energized phase numbers “2” and “3” where no energization is performed at the time of a U-phase wire break, the motor 10 can be continuously driven by allowing the motor 10 to pass through the regions with inertia.

In the case where a stagnation abnormality occurs during motor drive with two normal phases at the time of a one-phase wire break, the motor 10 driven with open-loop drive in which the motor rotation speed is lower than that with feedback control may not be able to pass through regions corresponding to the wire-broken phase with inertia. Therefore, in the present embodiment, if a stagnation abnormality occurs while range switching with two phases is performed at the time of a one-phase wire break, it is determined that the range switching is abnormal without shifting to open-loop drive.

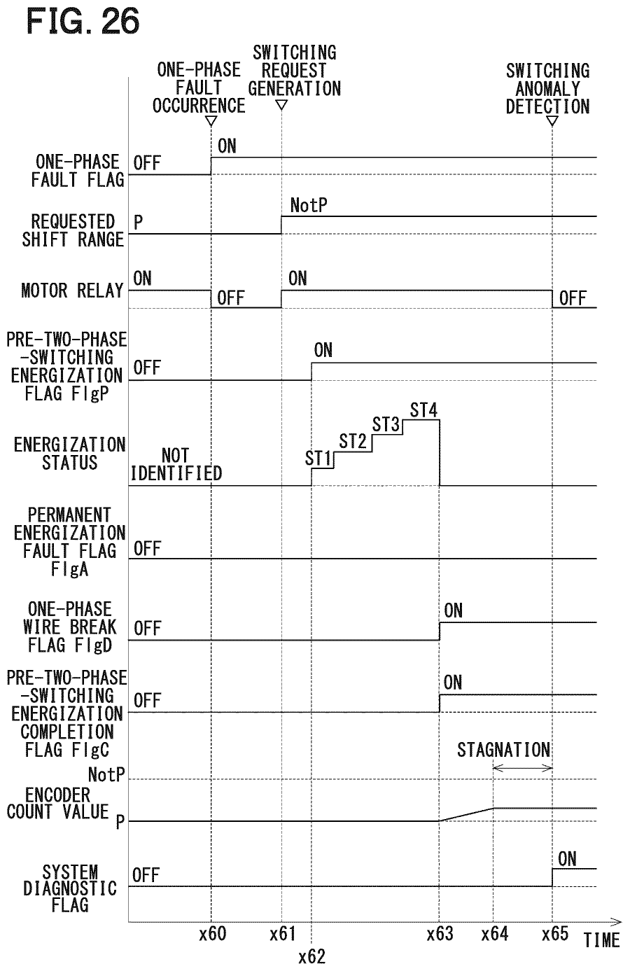

A range switching process at the time of a one-phase wire break will be described with reference to a time chart of FIG. 26. FIG. 26 illustrates the encoder count value and a system diagnostic flag below the items of FIG. 24, with the horizontal axis as a common time axis. For the encoder count value, the value when the detent roller 26 is fitted in the valley 211 is referred to as “P”, and the value when the detent roller 26 is fitted in the valley 212 as “notP”.

Processing from time x60 to time x63 is the same as the processing at the time of a one-phase wire break from time x50 to time x54 of FIG. 24. When the fault is identified as a one-phase wire break at time x63, range switching is performed with two normal phases. At time x64, the encoder count value stagnates before the detent roller 26 reaches the valley 212 that is a valley to be reached. At time x65 when a stagnation determination time has elapsed, without shifting to open-loop drive, the switching elements 411 to 413 are turned off to turn off the energization of the motor 10, and the motor relay 91 is turned off. The system diagnostic flag is turned on.

In the present embodiment, after a faulted phase is identified based on the port levels when the switching elements 411 to 413 are turned off, it is determined whether the fault is a wire break abnormality or a permanent energization abnormality due to a short to ground, based on the current detection value when the switching element of the faulted phase is turned on, and the rotational position of the motor 10 when the energization patterns for the normal phases are switched. This allows the accurate determination of whether a one-phase fault is a permanent energization abnormality or a wire break abnormality, regardless of the degree of a short to ground.

As described above, the ECU 40 controls the driving of the motor 10 including the motor windings 11 of three or more phases, and includes the drive circuit 41 and the control unit 50. The drive circuit 41 includes the switching elements 411 to 413 that turn on and off the energization of the phases of the motor windings 11.

The control unit 50 includes the drive control unit 55 and the abnormality determination unit 52. The drive control unit 55 controls the on-off operation of the switching elements 411 to 413. The abnormality determination unit 52 performs abnormality determination on energization paths to the motor windings 11.

The control unit 50 can acquire voltage detection values that are values detected by the voltage detection circuit 46 that detects the phase voltages of the motor windings 11, current detection values that are values detected by the current detection unit 45 that detects current passed through the motor windings 11, and the encoder signal that is the value detected by the encoder 13 that detects the rotational position of the motor 10.

The abnormality determination unit 52 identifies a faulted phase, based on the voltage detection values when the switching elements 411 to 413 of all the phases are turned off. The abnormality determination unit 52 identifies a permanent energization fault of the faulted phase, based on at least one of the current detection value when the switching element of the identified faulted phase is turned on, and the rotational position detection value when one or more of the switching elements 411 to 413 corresponding to one or more of normal phases are turned on.

This allows a fault condition to be accurately identified. Specifically, it can be accurately determined whether a fault occurring in a faulted phase is a permanent energization fault due to a short to ground or the like or a wire break fault that makes it impossible to energize the faulted phase.

Here, a fault condition identification process based on the current detection value when the switching element of a faulted phase is turned on is referred to as a “first fault condition identification process”, and a fault condition identification process based on the rotational position detection value at the time of normal phase energization as a “second fault condition identification process”. Performing at least one of the first fault condition identification process and the second fault condition identification process can be considered as performing the identification of the fault condition of the faulted phase.

In particular, the present embodiment uses the first fault condition identification process and the second fault condition identification process in combination, so that a permanent energization fault can be prevented from being erroneously determined as a wire break fault, regardless of variations in the degree of flow of current into a portion where the permanent energization fault has occurred (e.g. resistance at the time of a short to ground).

In the case where the motor current Im when the switching element of a faulted phase is turned on is greater than or equal to the current determination threshold Ith, the abnormality determination unit 52 identifies the fault as a permanent energization abnormality. By detecting current downstream of the switching element of a faulted phase when the switching element is turned on, if current flows, it can be determined that the wire is not broken in the faulted phase, that is, a permanent energization fault has occurred.

The abnormality determination unit 52 identifies a permanent energization fault based on the amount of change in the rotational position of the motor 10 between when a first normal phase energization process to energize one or more of normal phases is performed and when a second normal phase energization process to energize one or more of normal phases at least one of which is different from that in the first normal phase energization process is performed. In the present embodiment, the energization status ST13 to energize two normal phases corresponds to the “first normal phase energization process”, and the energization status ST14 to energize one normal phase corresponds to the “second normal phase energization process”. Specifically, when the rotational direction at the time of switching from the first normal phase energization process to the second normal phase energization process is different from that when all the phases are normal, the abnormality determination unit 52 identifies the fault as a permanent energization fault. Consequently, a permanent energization fault can be accurately identified.

Before the first normal phase energization process, the drive control unit 55 performs a pre-energization process to energize one or more of normal phases at least one of which is different from that in the first normal phase energization process. In the present embodiment, the energization status ST12 to energize one normal phase corresponds to the “pre-energization process”. When energization is first performed on any normal phase from a non-energized state, there are two positions at which the rotor 103 comes to rest due to the balance of attraction force, depending on the rotor position in the non-energized state. However, the second energization allows the rotor to be moved to an intended balanced position. Thus, in the present embodiment, after the pre-energization process is performed, the first normal phase energization process and the second normal phase energization process are performed, so that fault determination can be accurately performed regardless of the rotor position in a non-energized state.

The motor 10 is a three-phase motor. When there is one faulted phase and the fault is not identified as a permanent energization fault, the drive control unit 55 drives the motor 10 by energizing the motor windings 11 of two normal phases. Consequently, the motor 10 can be continuously driven. In the present embodiment, the present invention is applied to the shift-by-wire system 1, and the shift range can be switched at the time of a one-phase wire break.

When all the phases are normal and a stagnation abnormality in which the encoder count value stagnates occurs, the drive control unit 55 performs open-loop drive to switch energized phases without using the encoder count value, instead of feedback control based on the encoder count value. When there is one faulted phase and the fault is not a permanent energization fault, the drive control unit 55 drives the motor 10 by energizing the motor windings 11 of two normal phases with feedback control. If a stagnation abnormality occurs, the drive control unit 55 stops the drive control of the motor 10.

In the case of drive control with two normal phases at the time of a one-phase wire break, the motor 10 needs to pass through the wire-broken phase with inertia. With open-loop drive with a relatively slow rotation speed, the motor 10 may stop. Therefore, if a stagnation abnormality occurs at the time of a one-phase wire break, the control is stopped without shifting to open-loop drive, so that unnecessary energization can be avoided.

### Second Embodiment

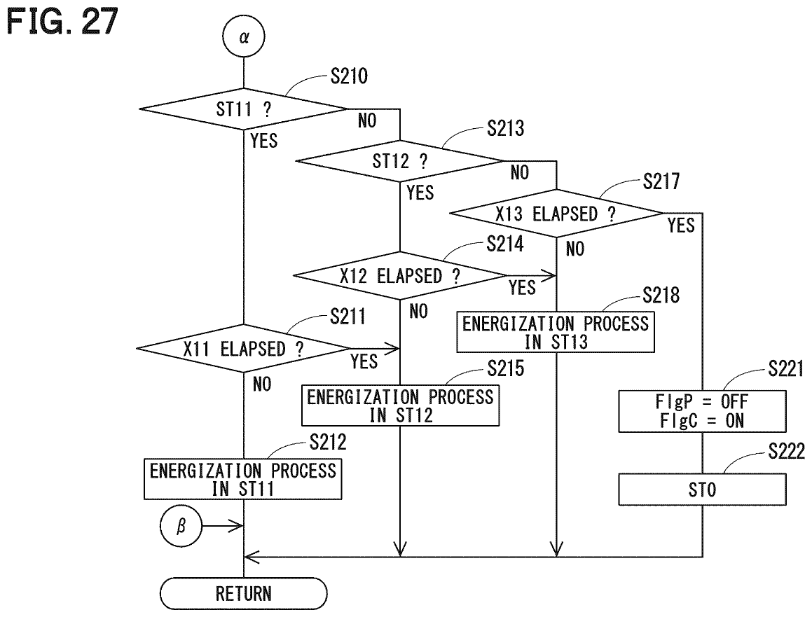

A second embodiment is illustrated in FIGS. 27 to 29. As described with reference to FIG. 17, when the energization status proceeds from the energization status ST12 with one-phase energization to the energization status ST13 with two-phase energization, the motor rotation angle does not change at the time of a short to ground. Therefore, in the present embodiment, when the motor rotation angle does not change at the time of switching from the one-phase energization to the two-phase energization, it is determined the fault is a permanent energization fault.

An energization process related to fault identification in the present embodiment is illustrated in a flowchart of FIG. 27. The first half is the same as FIG. 18 of the first embodiment, and thus the latter half corresponding to FIG. 19 is illustrated in FIG. 27. In the present embodiment, the energization status ST14 is not performed. Thus, S216, S219, and S220 are omitted in FIG. 27, which is the same as FIG. 19 except for this point. When a negative determination is made in S213, the process proceeds to S217. When an affirmative determination is made in S217, the process proceeds to S221.

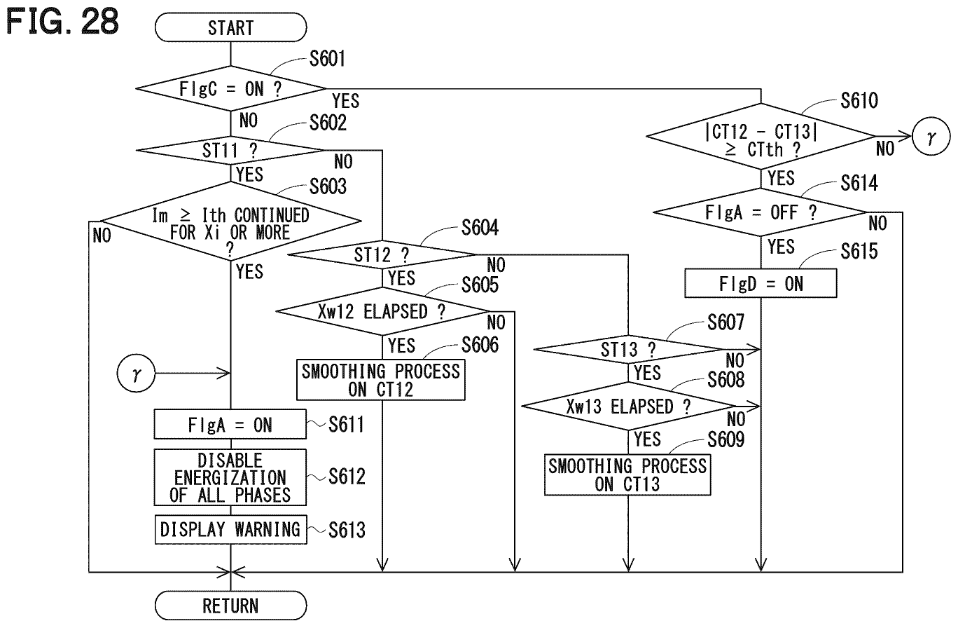

A fault condition determination process will be described with reference to a flowchart of FIG. 28. S601 to S603 are the same as S501 to S503 in FIG. 20. In S604 to which the process proceeds when a negative determination is made in S602, the abnormality determination unit 52 determines whether the current status is the energization status ST12. When it is determined that the current status is not the energization status ST12 (S604: NO), the process proceeds to S607. When it is determined that the current status is the energization status ST12 (S604: YES), the process proceeds to S605.

In S605, the abnormality determination unit 52 determines whether the standby time Xw12 has elapsed since the start of the energization status ST12. When it is determined that the standby time Xw12 has not elapsed since the start of the energization status ST12 (S605: NO), the subsequent processing is skipped. When it is determined that the standby time Xw12 has elapsed since the start of the energization status ST12 (S605: YES), the process proceeds to S606 to perform a count value smoothing process to calculate a count value CT12 after the smoothing process (see formula (1)). In the formula, a subscript (n) represents a current value, and (n−1) represents a previous value.

$$CT {12}_{( n )} = ( 2 \times CT {12}_{( n - 1 )} - EN ) / 3 \qquad ( 1 )$$

In S607 to which the process proceeds when it is determined that the current status is not the energization status ST12 (S604: NO), the abnormality determination unit 52 determines whether the current status is the energization status ST13. When it is determined that the current status is not the energization status ST13 (S607: NO), the subsequent processing is skipped. When it is determined that the current status is the energization status ST13 (S607: YES), the process proceeds to S608.

In S608, the abnormality determination unit 52 determines whether the standby time Xw13 has elapsed since the start of the energization status ST13. When it is determined that the standby time Xw13 has not elapsed (S608: NO), the subsequent processing is skipped. When it is determined that the standby time Xw13 has elapsed (S608: YES), the process proceeds to S609 to perform a count value smoothing process to calculate a count value CT13 after the smoothing process (see formula (2)).

$$CT {13}_{( n )} = ( 2 \times CT {13}_{( n - 1 )} - EN ) / 3 \qquad ( 2 )$$

In S610 to which the process proceeds when it is determined that the pre-two-phase-switching energization completion flag FlgC is on (S601: YES), the abnormality determination unit 52 determines whether the absolute value of the difference between the count values CT12 and CT13 after the smoothing processes is greater than or equal to a difference determination threshold ΔCTth. The difference determination threshold ΔCTth is set to a value close to zero so that it can be determined that the rotor 103 has not moved at the time of proceeding from the energization status ST12 to ST13. When it is determined that the absolute value of the difference between the count values CT12 and CT13 is less than the difference determination threshold ΔCTth (S610: NO), it is determined that the fault is a permanent energization fault, and the process proceeds to S611. When it is determined that the absolute value of the difference between the count values CT12 and CT13 is greater than or equal to the difference determination threshold ΔCTth (S610: YES), it is determined that the fault is a wire break fault, not a permanent energization fault, and the process proceeds to S614. Processing in S611 to S615 is the same as that in steps S511 to S515 in FIG. 20.

A range switching process in the present embodiment will be described with reference to a time chart of FIG. 29. A case where it is determined that the fault is a permanent energization fault in the energization status ST11 is the same as that in the first embodiment, and thus the description thereof is omitted. Processing from time x60 to time x62 is the same as the processing from time x50 to time x52 in FIG. 24.

At and after time x62, energization in the energization statuses ST11, ST12, and ST13 is sequentially performed. When the energization status ST13 ends at time x63, the pre-two-phase-switching energization completion flag FlgC is turned on. Here, when the fault is identified as a permanent energization fault, based on the difference between the count values CT12 and CT13, the permanent energization fault flag FlgA is turned on and the motor relay 91 is turned off as indicated by two-dot chain lines.

When the fault is not identified as a permanent energization fault, based on the count values CT12 and CT13, the fault is identified as a one-phase wire break, and the one-phase wire break flag FlgD is turned on as indicated by a solid line. Processing at and after time x63 is the same as the processing at and after time x54 in FIG. 24.

In the present embodiment, in the case where the amount of change in the encoder count value is less than the difference determination threshold ΔCTth when the switching elements of all normal phases are turned on in the second normal phase energization process, the fault is identified as a permanent energization fault. In the present embodiment, the energization status ST12 corresponds to the “first normal phase energization process”, and the energization status ST13 corresponds to the “second normal phase energization process”. Consequently, a permanent energization fault can be accurately identified. The same effects as those of the above embodiment are achieved.

### Third Embodiment

A third embodiment is illustrated in FIGS. 30 to 36. In the above embodiment, at the time of a one-phase fault, it is determined whether the fault is a wire break or a short to ground in the faulted phase, based on the motor rotation angle when energized phases are switched from one-phase energization to two-phase energization to one-phase energization, with the energization status ST12 as the one-phase energization, the energization status ST13 as the two-phase energization, and the energization status ST14 as the one-phase energization. In the present embodiment, with the energization statuses ST22 to ST24 all as one-phase energization, the abnormality condition of a faulted phase is determined based on the motor rotation angle when energized phases are switched.

FIGS. 30 to 33 illustrate, from the top, an energization status ST21 in which the switching elements 411 to 413 of all the phases are turned off, an energization status ST22 in which the V-phase switching element 412 is turned on, an energization status ST23 in which the W-phase switching element 413 is turned on, and an energization status ST24 in which the V-phase switching element 412 is turned on. Energized phases are switched in this order in the description. The energization statuses ST21 and ST22 are the same as the energization statuses ST11 and 12 of the above embodiments, and thus the description thereof is omitted as appropriate.

FIG. 30 illustrates a case where the recesses 105 of the rotor 103 do not face the V-phase when all the phases are off at the time of a U-phase wire break. When the energization status proceeds from ST22 to ST23 to turn off the V-phase switching element 412 and turn on the W-phase switching element 413 to proceed to W-phase energization, the projections 104 of the rotor 103 rotate +15° to positions to face the W-phase. That is, the rotation angle difference Δθ when the energization status proceeds from ST22 to ST23 is +15°.

When the energization status proceeds from ST23 to ST24 to turn on the V-phase switching element 412 and turn off the W-phase switching element 413 to proceed to V-phase energization, the projections 104 rotate −15° to positions to face the V-phase. That is, the rotation angle difference Δθ when the energization status proceeds from ST23 to ST24 is −15°.

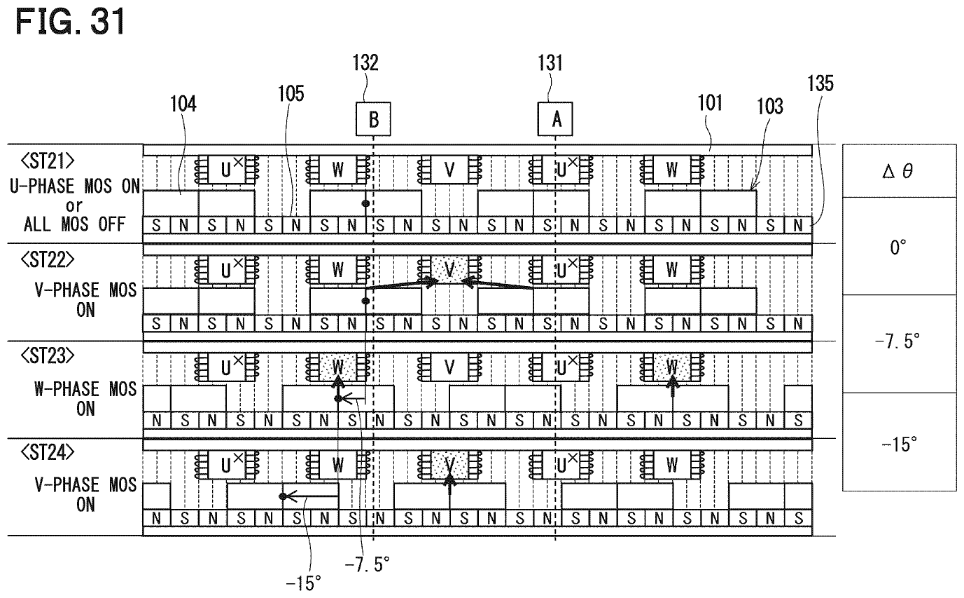

FIG. 31 illustrates a case where the recesses 105 of the rotor 103 face the V-phase when all the phases are off at the time of a U-phase wire break. When the energization status proceeds from ST22 to ST23 to turn off the V-phase switching element 412 and turn on the W-phase switching element 413 to proceed to W-phase energization, the projections 104 rotate −7.5° to positions to face the W-phase. That is, the rotation angle difference Δθ when the energization status proceeds from ST22 to ST23 is −7.5°.

When the energization status proceeds from ST23 to ST24 to turn on the V-phase switching element 412 and turn off the W-phase switching element 413 to proceed to V-phase energization, the projections 104 rotate −15° to positions to face the V-phase. That is, as in FIG. 30, the rotation angle difference Δθ when the energization status proceeds from ST23 to ST24 is −15°.

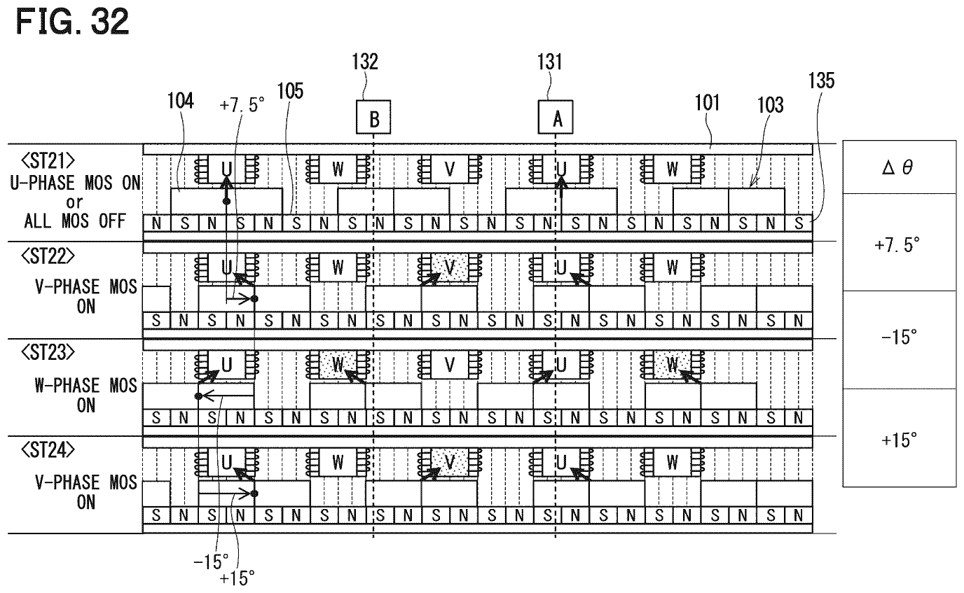

FIG. 32 illustrates a case where in the energization status ST21, the U-phase coils 111 are energized due to a U-phase short to ground, and the projections 104 face the U-phase. When the energization status proceeds from ST22 to ST23 to turn off the V-phase switching element 412 and turn on the W-phase switching element 413, the W-phase and U-phases are energized, and the projections 104 rotate −15° to positions to face the U-phase and the W-phase. That is, the rotation angle difference Δθ when the energization status proceeds from ST22 to ST23 is −15°.

When the energization status proceeds from ST23 to ST24 to turn on the V-phase switching element 412 and turn off the W-phase switching element 413, the U-phase and V-phases are energized, and the projections 104 rotate +15° to positions to face the U-phase and the V-phase. That is, the rotation angle difference Δθ when the energization status proceeds from ST23 to ST24 is +15°.

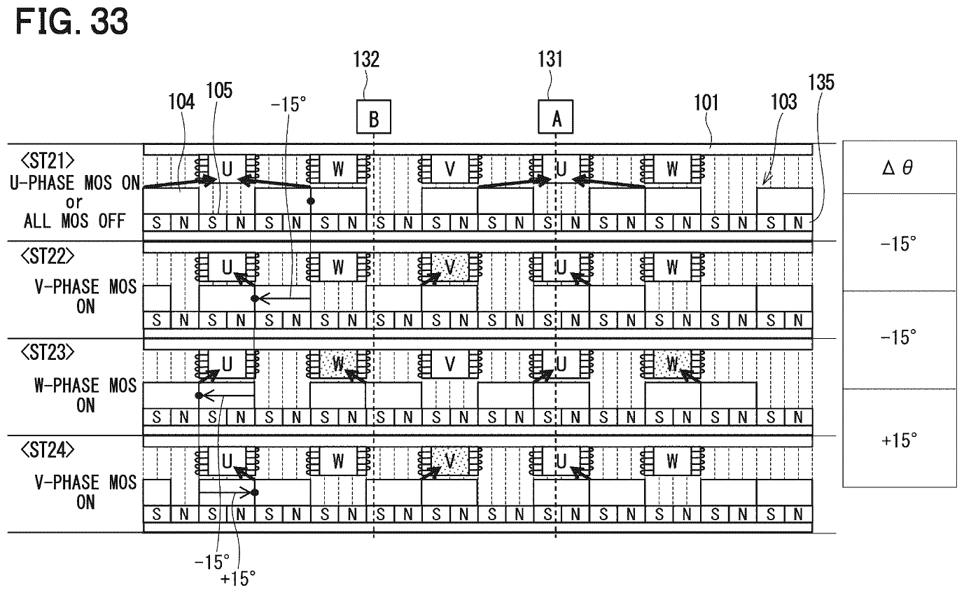

FIG. 33 illustrates a case where in the energization status ST21, the U-phase coils 111 are energized due to a U-phase short to ground, and the recesses 105 face the U-phase. When the energization status proceeds from ST22 to ST23 to turn off the V-phase switching element 412 and turn on the W-phase switching element 413, the W-phase and U-phases are energized, and the projections 104 rotate −15° to positions to face the U-phase and the W-phase. That is, the rotation angle difference Δθ when the energization status proceeds from ST22 to ST23 is −15°.

When the energization status proceeds from ST23 to ST24 to turn on the V-phase switching element 412 and turn off the W-phase switching element 413, the U-phase and V-phases are energized, and the projections 104 rotate +15° to positions to face the U-phase and the V-phase. That is, as in FIG. 32, the rotation angle difference Δθ when the energization status proceeds from ST23 to ST24 is +15°.

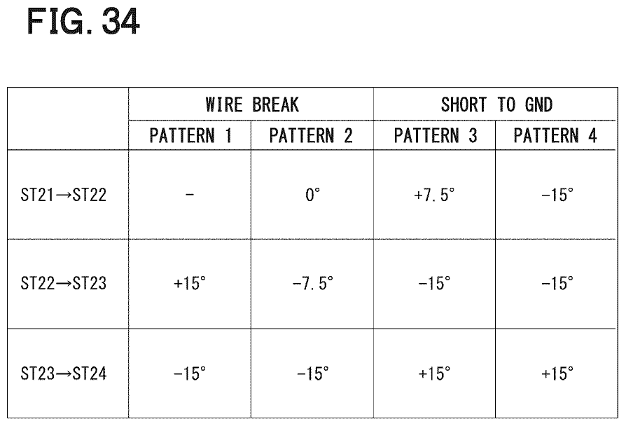

FIG. 34 is a diagram for explaining the rotation angle difference Δθ in response to the switching between the energization statuses ST21 to ST24. Pattern 1 in FIG. 34 corresponds to FIG. 30 and is a pattern in which in the energization status ST21, the recesses 105 do not face the phase to be energized in the energization status ST22. Pattern 2 corresponds to FIG. 31 and is a pattern in which in the energization status ST21, the recesses 105 face the phase to be energized in the energization status ST22. Pattern 3 corresponds to FIG. 32 and is a pattern in which in the energization status ST21, the projections 104 face the phase with a permanent energization fault. Pattern 4 corresponds to FIG. 33, and is a pattern in which in the energization status ST21, the recesses 105 face the phase with a permanent energization fault.

As illustrated in FIG. 34, in the case where the energized phases are switched from the energization status ST21 to ST24, at the time of proceeding from the energization status ST23 to ST24, the rotational direction of the rotor 103 when a U-phase wire break has occurred is different from that when a short to ground has occurred, regardless of the rotor position in the energization status ST21. Therefore, it is possible to determine whether the fault is a wire break or a short to ground. In particular, at the time of a short to ground with small resistance that is difficult to determine based on the current value when a faulted phase is on, an energized state when the switching element of one normal phase is turned on is closer to a state with two-phase energization, and encoder outputs are likely to stabilize under conditions similar to those at the time of two-phase energization and thus facilitate the determination.

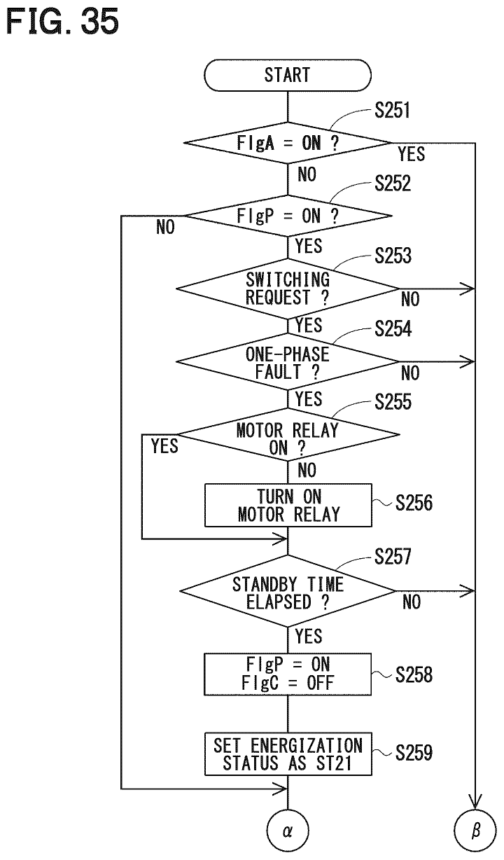

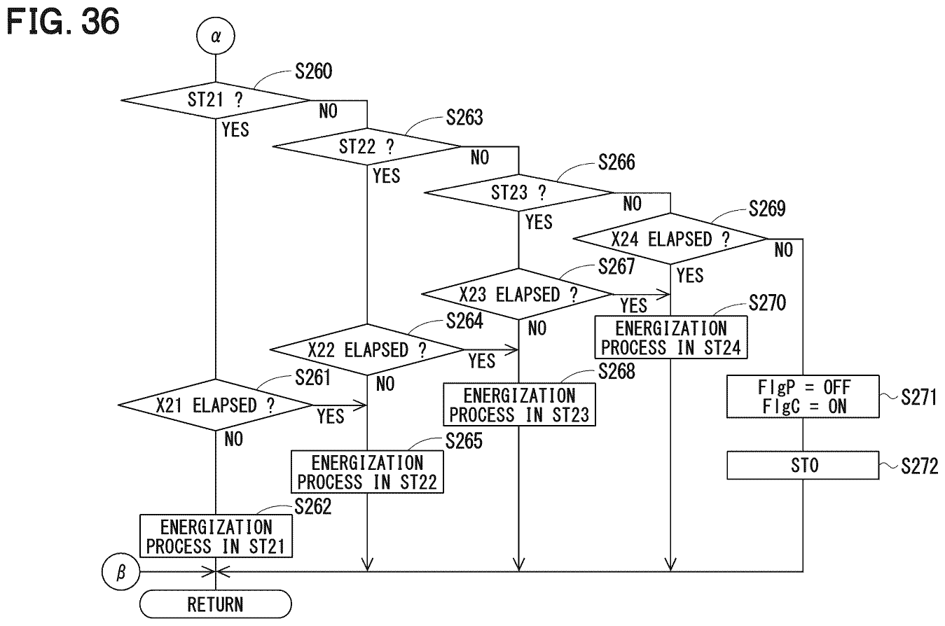

An energization process related to faulted phase identification will be described with reference to flowcharts of FIGS. 35 and 36. Processing in S251 to S258 in FIG. 35 is the same as the processing in S201 to S208 in FIG. 18. In S259, the control unit 50 sets the status as the energization status ST21.

As illustrated in FIG. 36, in S260, the control unit 50 determines whether the current status is the energization status ST21. When it is determined that the current status is not the energization status ST21 (S260: NO), the process proceeds to S263. When it is determined that the current status is the energization status ST21 (S260: YES), the process proceeds to S261.

In S261, the control unit 50 determines whether a duration X21 has elapsed since the start of the energization status ST21. When it is determined that the duration X21 has elapsed (S261: YES), the status is set as the energization status ST22, and the process proceeds to S265. When it is determined that the duration X21 has not elapsed (S261: NO), the process proceeds to S262.

In S262, the control unit 50 performs energization in the energization status ST21. The energization status ST21 is faulted-phase energization. When the U-phase fault flag has been turned on, the U-phase switching element 411 is turned on. When the V-phase fault flag has been turned on, the V-phase switching element 412 is turned on. When the W-phase fault flag has been turned on, the W-phase switching element 413 is turned on.

In S263 to which the process proceeds when it is determined that the current status is not the energization status ST21 (S260: NO), the control unit 50 determines whether the current status is the energization status ST22. When it is determined that the current status is not the energization status ST22 (S263: NO), the process proceeds to S266. When it is determined that the current status is the energization status ST22 (S263: YES), the process proceeds to S264.

In S264, the control unit 50 determines whether a duration X22 has elapsed since the start of the energization status ST22. When it is determined that the duration X22 has elapsed (S264: YES), the status is set as the energization status ST23, and the process proceeds to S268. When it is determined that the duration X22 has not elapsed (S264: NO), the process proceeds to S265.

In S265, the control unit 50 performs energization in the energization status ST22. The energization status ST22 is one-normal-phase energization. When the U-phase fault flag has been turned on, the V-phase switching element 412 is turned on. When the V-phase fault flag has been turned on, the W-phase switching element 413 is turned on. When the W-phase fault flag has been turned on, the U-phase switching element 411 is turned on.

In S266 to which the process proceeds when it is determined that the current status is not the energization status ST22 (S263: NO), the control unit 50 determines whether the current status is the energization status ST23. When it is determined that the current status is not the energization status ST23 (S266: NO), the process proceeds to S269. When it is determined that the current status is the energization status ST23 (S266: YES), the process proceeds to S267.

In S267, the control unit 50 determines whether a duration X23 has elapsed since the start of the energization status ST23. When it is determined that the duration X23 has elapsed (S267: YES), the status is set as the energization status ST24, and the process proceeds to S270. When it is determined that the duration X23 has not elapsed (S267: NO), the process proceeds to S268.

In S268, the control unit 50 performs energization in the energization status ST23. The energization status ST23 is one-normal-phase energization different from that in the energization status ST22. When the U-phase fault flag has been turned on, the W-phase switching element 413 is turned on. When the V-phase fault flag has been turned on, the U-phase switching element 411 is turned on. When the W-phase fault flag has been turned on, the V-phase switching element 412 is turned on.

In S269 to which the process proceeds when it is determined that the current status is not the energization status ST23 (S266: NO), the control unit 50 determines whether a duration X24 has elapsed since the start of the energization status ST24. The durations X21 to X24 can be set as desired. At least some of the durations X21 to X24 may be the same or different. When it is determined that the duration X24 has not elapsed (S269: NO), the process proceeds to S271. When it is determined that the duration X24 has elapsed (S269: YES), the process proceeds to S270.

In S270, the control unit 50 performs energization in the energization status ST24. The energization status ST24 is the same one-normal-phase energization as the energization status ST22. When the U-phase fault flag has been turned on, the V-phase switching element 412 is turned on. When the V-phase fault flag has been turned on, the W-phase switching element 413 is turned on. When the W-phase fault flag has been turned on, the U-phase switching element 411 is turned on. Processing in S271 and S272 is the same as that in S221 and S222 in FIG. 19.

A fault condition determination process and a range switching process are the same as those of the first embodiment if the energization statuses ST11 to ST14 are read as ST21 to ST24, and thus the description thereof is omitted. In the first embodiment, since the energization status ST13 is two-phase energization, the standby time Xw13 in the energization status ST13 is set to be shorter than the standby time Xw14 in the energization status ST14. In the present embodiment, since the energization statuses ST23 and ST24 are both one-phase energization, it is desirable that a standby time Xw23 in the energization status ST23 is equivalent to a standby time Xw24 in the energization status ST24.

In the present embodiment, the energization status ST23 to energize one normal phase corresponds to the “first normal phase energization process”, and the energization status ST24 to energize one normal phase different from that in the energization status ST23 corresponds to the “second normal phase energization process”. The energization status ST22 corresponds to the “pre-energization process”. This configuration also achieves the same effects as the above embodiments.

### Fourth Embodiment

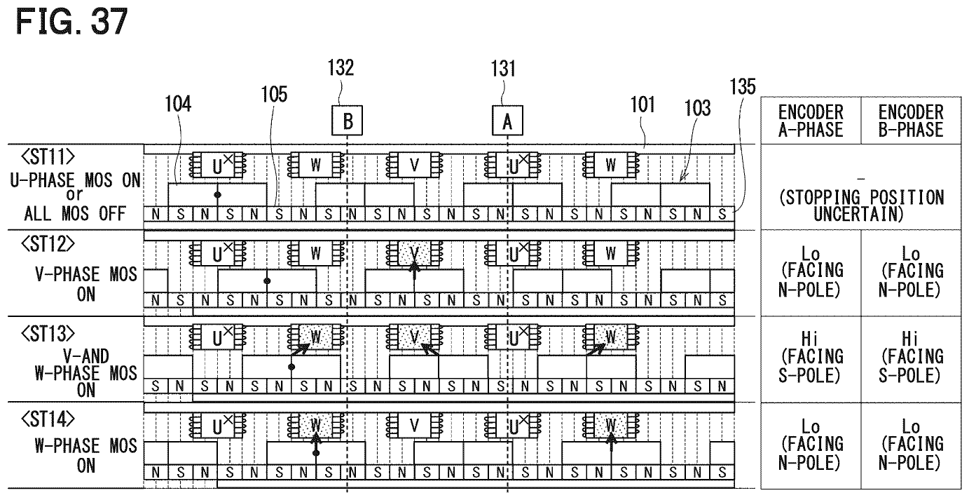

A fourth embodiment is illustrated in FIGS. 37 to 41. In the above embodiments, it is determined whether the fault is a short to ground or a wire break abnormality, based on the motor rotation angle when the energization patterns for the normal phases are switched. In the present embodiment, it is determined whether the fault is a short to ground or a wire break abnormality, based on encoder outputs at the time of one-phase energization.

Left-side portions of FIGS. 37 to 40 are the same as those of FIGS. 13 to 16 of the first embodiment. Right-side portions illustrate A-phase and B-phase encoder outputs. FIG. 37 illustrates a case where the recesses 105 of the rotor 103 do not face the V-phase when all the phases are off at the time of a U-phase wire break. When all the phases are off, no attraction force of the motor windings 11 is generated, and thus the position of the rotor 103 is uncertain. At the time of a U-phase wire break, even when the U-phase switching element 411 is turned on, the motor windings 11 are not energized, thus resulting in the same state.

When the energization status proceeds from ST11 to ST12 to turn on the V-phase switching element 412 to energize the V-phase, the projections 104 of the rotor 103 face the V-phase. At this time, both the A-phase and the B-phase face north poles, and the encoder outputs are Lo.

When the energization status proceeds from ST12 to ST13 to turn on the V-phase and W-phase switching elements 412 and 413 to energize the V-phase and W-phases, the projections 104 face the V-phase and the W-phase. At this time, both the A-phase and the B-phase face south poles, and the encoder outputs are Hi.

When the energization status proceeds from ST13 to ST14 to turn off the V-phase switching element 412 and turn on the W-phase switching element 413 to energize the W-phase, the projections 104 face the W-phase. At this time, both the A-phase and the B-phase face north poles, and the encoder outputs are Lo.

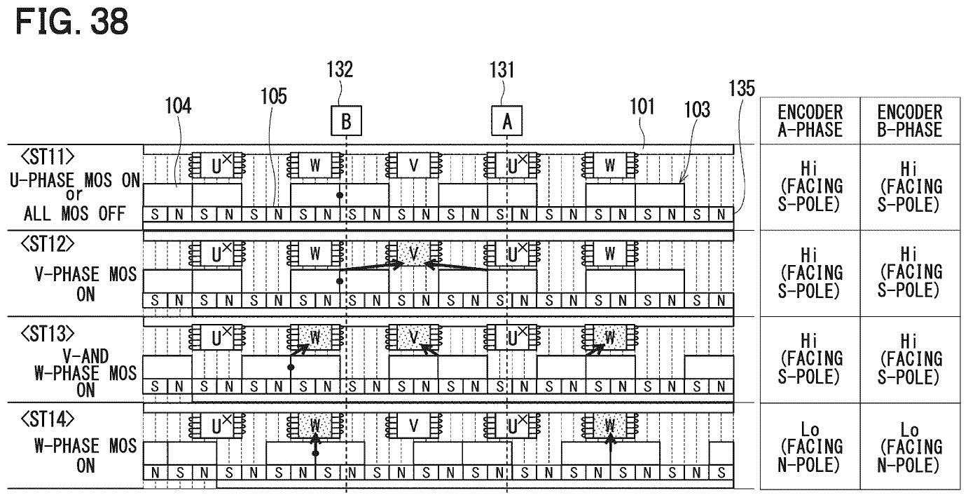

FIG. 38 illustrates a case where the recesses 105 of the rotor 103 face the V-phase when all the phases are off at the time of a U-phase wire break. When the recesses 105 face the V-phase while all the phases are off, both the A-phase and the B-phase face south poles, and the encoder outputs are Hi.

When the energization status proceeds from ST11 to ST12 to turn on the V-phase switching element 412 to energize the V-phase, the coils 112 are energized. When the recesses 105 face the V-phase, the left and right projections 104 are attracted to the V-phase, so that the recesses 105 remain facing the V-phase. At this time, both the A-phase and the B-phase face south poles, and the encoder outputs are Hi, which are different from the encoder outputs when the recesses 105 do not face the V-phase while energization is off.

When the energization status proceeds from ST12 to ST13 to turn on the V-phase and W-phase switching elements 412 and 413 to energize the V-phase and W-phases, the projections 104 face the V-phase and the W-phase. At this time, both the A-phase and the B-phase face south poles, and the encoder outputs are Hi.

When the energization status proceeds from ST13 to ST14 to turn on the W-phase switching element 413 to energize the W-phase, the projections 104 face the W-phase. At this time, both the A-phase and the B-phase face north poles, and the encoder outputs are Lo. That is, by performing two-phase energization once and then performing one-phase energization, a so-called “one phase to one tooth” state is obtained in which one projection 104 faces one energized phase, regardless of the rotor position when all the phases are off, and the encoder outputs become Lo.

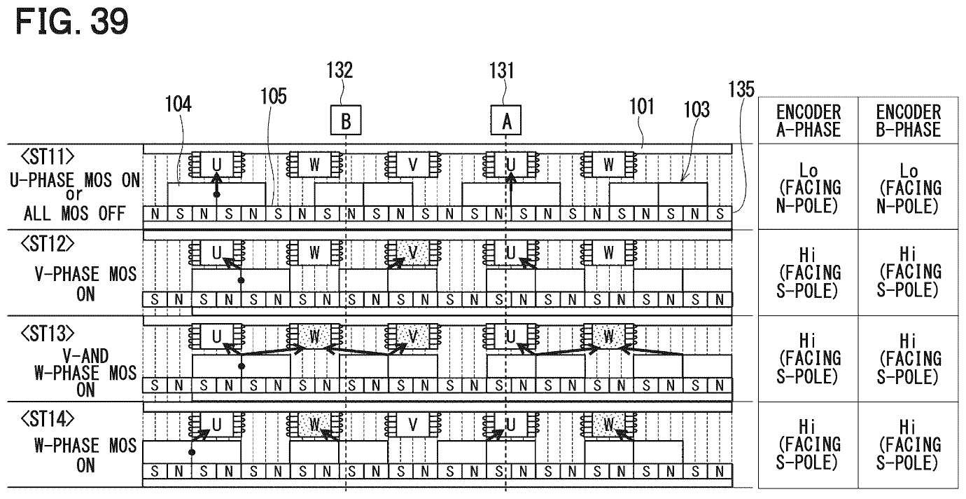

FIG. 39 illustrates a case where when all the phases are off, the U-phase coils 111 are energized due to a U-phase short to ground, and the projections 104 of the rotor 103 face the U-phase. When the projections 104 face the U-phase, both the A-phase and the B-phase face north poles, and the encoder outputs are Lo.

When the energization status proceeds from ST11 to ST12 to turn on the V-phase switching element 412, the U-phase and V-phases are energized due to the U-phase short to ground, and the projections 104 face the U-phase and the V-phase. At this time, both the A-phase and the B-phase face south poles, and the encoder outputs are Hi. At this time, the W-phase faces the recesses 105.

When the energization status proceeds from ST12 to ST13 to turn on the V-phase and W-phase switching elements 412 and 413, W-phase energization is added, but the rotor 103 does not rotate because the W-phase faces the recesses 105, and the state in which both the A-phase and the B-phase face south poles and the encoder outputs are Hi is maintained.

When the energization status proceeds from ST13 to ST14 to turn on the W-phase switching element 413, the W-phase and U-phases are energized due to the U-phase short to ground, and the projections 104 face the U-phase and the W-phase. At this time, both the A-phase and the B-phase face south poles, and the encoder outputs are Hi.

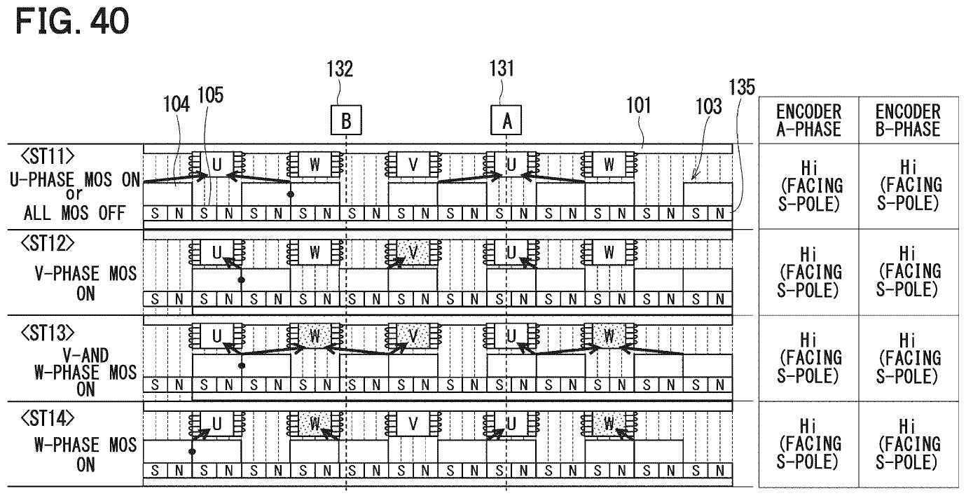

FIG. 40 illustrates a case where when all the phases are off, the U-phase coils 111 are energized due to a U-phase short to ground, and the recesses 105 of the rotor 103 face the U-phase. When the recesses 105 face the U-phase, both the A-phase and the B-phase face south poles, and the encoder outputs are Hi.

When the energization status proceeds from ST11 to ST12 to turn on the V-phase switching element 412, the U-phase and V-phases are energized due to the U-phase short to ground, and the projections 104 face the U-phase and the V-phase. At this time, both the A-phase and the B-phase face south poles, and the encoder outputs are Hi. The subsequent turning on the V-phase and W-phases and turning on the W-phase are the same as those in FIG. 39, and thus the description thereof is omitted.

In the case where the U-phase is shorted to ground, even when one normal phase is energized, the U-phase is also energized, so that the two phases are energized, resulting in different encoder outputs. Consequently, it can be determined whether the fault is a wire break or a short to ground. In particular, at the time of a short to ground with small resistance that is difficult to determine based on the current value when a faulted phase is on, the state is closer to that with two-phase energization than that at the time of an incomplete short to ground, and the encoder outputs are likely to stabilize under conditions similar to those at the time of two-phase energization and thus facilitates the determination.

In FIGS. 37 to 40, when energization is switched from one-phase energization to two-phase energization to one-phase energization at the time of a U-phase fault, the energization status ST12 is described as V-phase energization, and the energization status ST14 after the two-phase energization as W-phase energization. However, any phase may be energized in the one-phase energization performed twice. For example, the same phase may be energized like V-phase energization to V-phase and W-phase energization to V-phase energization. The first one-phase energization may be omitted to start from the two-phase energization.

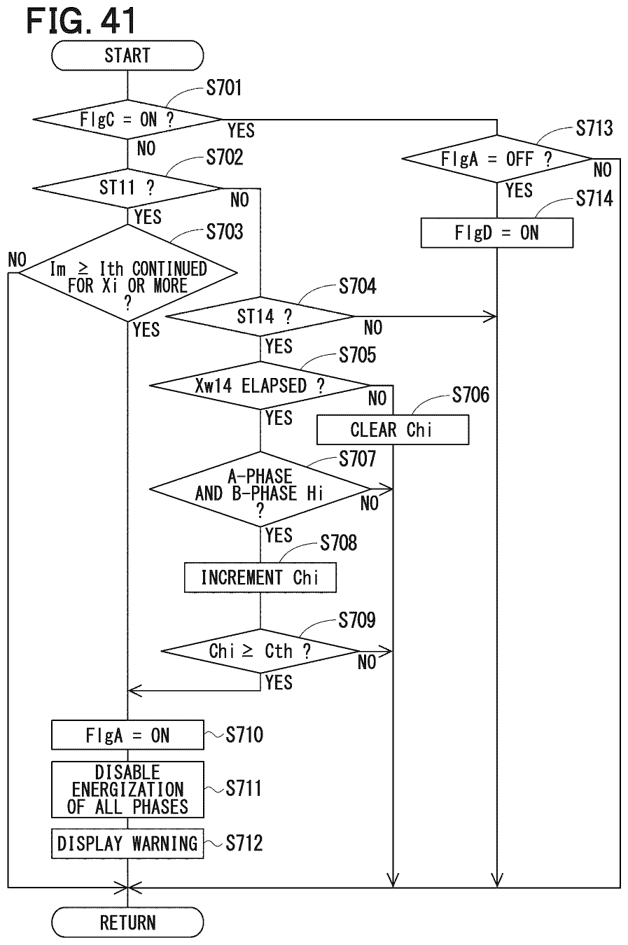

An energization process related to faulted phase identification of the present embodiment is the same as that of the first embodiment, and thus the description thereof is omitted. A fault condition determination process of the present embodiment will be described with reference to a flowchart of FIG. 41. Processing in S701 to S703 is the same as the processing in S501 to S503 in FIG. 20. When an affirmative determination is made in S701, the process proceeds to S713.

Processing in S704 and S705 to which the process proceeds when it is determined that the current status is not the energization status ST11 (S702: NO) is the same as the processing in S507 and S508 in FIG. 20. When it is determined in S705 that the standby time Xw14 has not elapsed since the start of the energization status ST14 (S705: NO), the process proceeds to S706 to clear a counter Chi. When it is determined that the standby time Xw14 has elapsed (S705: YES), the process proceeds to S707.

In S707, it is determined whether both the A-phase and B-phase encoder outputs are Hi. A state in which both the A-phase and B-phase encoder outputs are Hi is a signal pattern when two phases face two teeth at the time of two-phase energization. When it is determined that at least one of the A-phase and B-phase encoder outputs is Lo (S707: NO), the subsequent processing is skipped. When it is determined that both the A-phase and B-phase encoder outputs are Hi (S707: YES), the process proceeds to S708 to increment the counter Chi.

In S709, the abnormality determination unit 52 determines whether the counter Chi is greater than or equal to a count determination threshold Cth. When it is determined that the counter Chi is less than the count determination threshold Cth (S709: NO), the subsequent processing is skipped. When it is determined that the counter Chi is greater than or equal to the count determination threshold Cth (S709: YES), the process proceeds to S710. Processing in S710 to S714 is the same as the processing in S511 to S515 in FIG. 20. A range switching process is the same as that of the first embodiment except that details of fault determination are different.

A rotation detection unit of the present embodiment is the encoder 13. The abnormality determination unit 52 identifies the fault as a permanent energization fault in the case where the encoder signal pattern when one of the normal phases is energized is the pattern at the time of two-phase energization. Consequently, a permanent energization fault can be accurately identified. The same effects as those of the above embodiments are achieved.

In the present embodiment, as in the first embodiment, the energization status ST13 to energize two normal phases corresponds to the “first normal phase energization process”, and the energization status ST14 to energize one normal phase corresponds to the “second normal phase energization process”.

### Fifth Embodiment

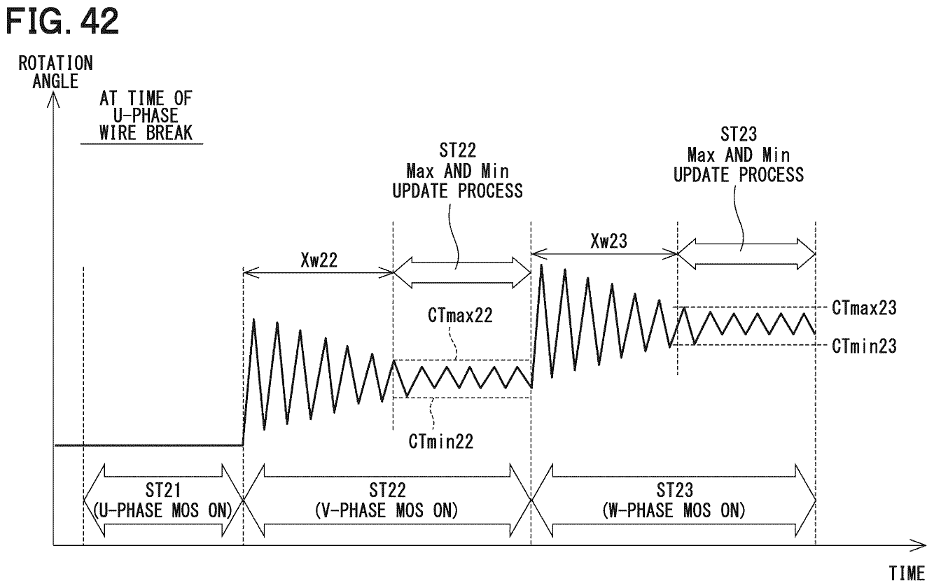

A fifth embodiment is illustrated in FIGS. 42 to 48. As described in the above embodiments, when the switching element of one normal phase is turned on at the time of a one-phase fault, the one phase is energized if the fault is a wire break fault, and the two phases are energized when the fault is a permanent energization fault due to a short to ground. When two phases are energized, the convergence of rotational vibration due to energized phase switching is good as compared with one-phase energization. Therefore, the present embodiment uses the fact that a vibration convergence characteristic differs between one-phase energization and two-phase energization, to determine whether a fault is a wire break fault or a short to ground.

The behavior of the rotor 103 when energization patterns for the V-phase and the W-phase, which are normal phases, are switched at the time of a U-phase fault will be described with reference to FIGS. 42 to 44. In FIGS. 42 to 44, the horizontal axis represents time, and the vertical axis represents the motor rotation angle.

FIG. 42 illustrates a case where at the time of a U-phase wire break, the projections 104 of the rotor 103 do not face the V-phase in the energization status ST21. Even when the switching element 411 of the U-phase, which is a faulted phase, is turned on in the energization status ST21, the motor windings 11 are not energized, and thus the rotor 103 does not move.

When the energization status proceeds from ST21 to ST22 to turn off the U-phase switching element 411 and turn on the V-phase switching element 412, the rotor 103 rotates to a position where the projections 104 face the V-phase. At this time, since one-phase energization is performed, vibration is relatively large even after the elapse of a standby time Xw22.

When the energization status proceeds from ST22 to ST23 to turn off the V-phase switching element 412 and turn on the W-phase switching element 413, the rotor 103 rotates to a position where the projections 104 face the W-phase. At this time, since one-phase energization is performed, vibration is relatively large even after the elapse of the standby time Xw23.

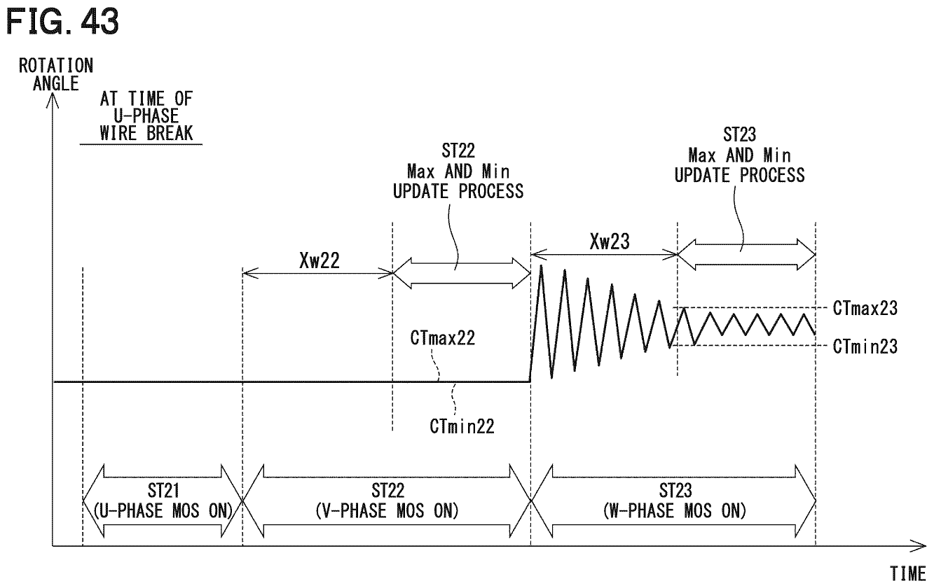

FIG. 43 illustrates a case where at the time of a U-phase wire break, the projections 104 of the rotor 103 face the V-phase in the energization status ST21. The behavior in the energization status ST21 is the same as that in FIG. 42.

The energization status proceeds from ST21 to ST22 to turn off the U-phase switching element 411 and turn on the V-phase switching element 412. In this example, since the projections 104 face the V-phase in the energization status ST21, the rotor 103 does not move even when the V-phase is energized, and the rotation angle does not change. Similarly, when the recesses 105 face the V-phase in the energization status ST21, the rotation angle does not change. That is, in the energization status ST21, the rotor position is uncertain. If the projections 104 or the recesses 105 of the rotor 103 face the V-phase at positions near, the vibration of the rotor 103 is small even when switching to V-phase energization is performed.

The behavior when the energization status proceeds from ST22 to ST23 is the same as that in FIG. 42. The rotor 103 rotates to a position where the projections 104 face the W-phase due to W-phase energization. At this time, since one-phase energization is performed, vibration is relatively large even after the elapse of the standby time Xw23.

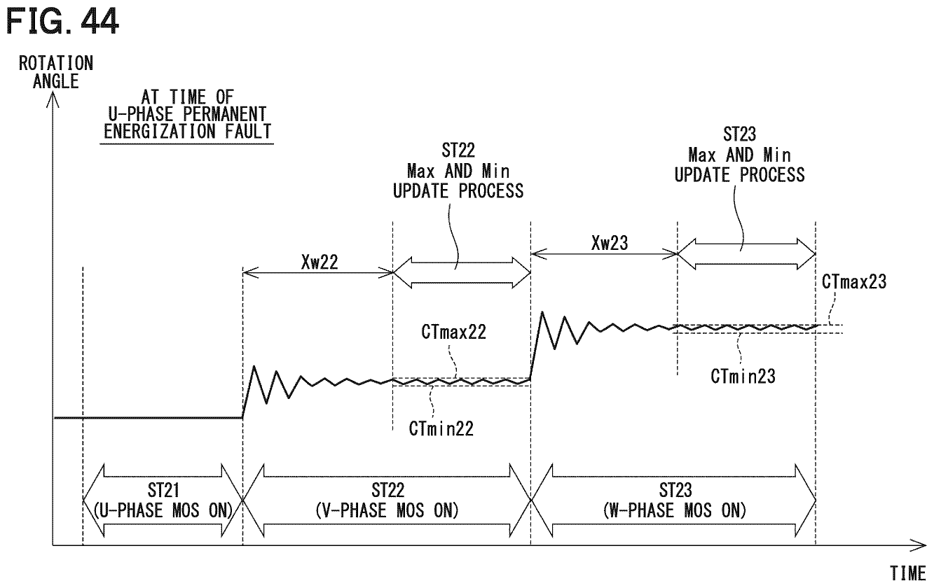

FIG. 44 illustrates a case of a U-phase permanent energization fault. In the energization status ST21, when the U-phase switching element 411 is turned on, the U-phase coils 111 are energized, and, for example, the projections 104 face the U-phase.

When the energization status proceeds from ST21 to ST22 to turn off the U-phase switching element 411 and turn on the V-phase switching element 412, two phases, the U-phase and V-phases, are energized, and the rotor 103 rotates to a position where the projections 104 face the U-phase and the V-phase.

When the energization status proceeds from ST22 to ST23 to turn off the V-phase switching element 412 and turn on the W-phase switching element 413, two phases, the W-phase and U-phases, are energized, and the rotor 103 rotates to a position where the projections 104 face the U-phase and the W-phase.

When a permanent energization fault has occurred, two phases are energized in the energization statuses ST22 and ST23, and the convergence of vibration is better than that at the time of a wire break fault that results in one-phase energization. Therefore, the present embodiment uses the differences between maximum values and minimum values after the elapse of the standby times Xw22 and Xw23 in the energization statuses ST22 and ST23, to determine whether the fault is a one-phase wire break or a short to ground.

As described with reference to FIG. 43, even at the time of a one-phase wire break, switching of the energization status from ST21 to ST22 may not cause the rotor 103 to move, depending on the rotor position in the energization status ST21. Thus, determination only at the time of switching to the energization status ST22 may be erroneous. Therefore, in the present embodiment, determination is performed in the energization statuses ST22 and ST23.

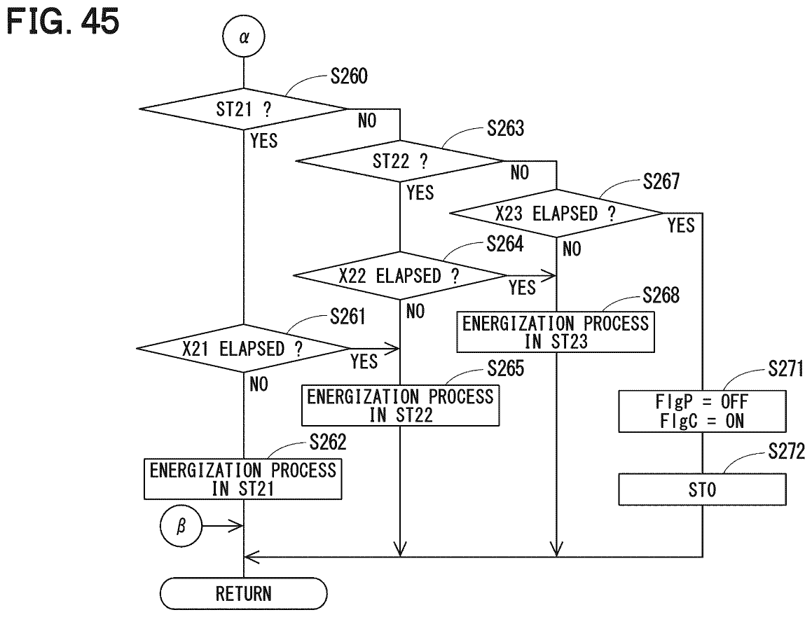

An energization process related to fault identification in the present embodiment is illustrated in a flowchart of FIG. 45. The first half is the same as FIG. 35 of the second embodiment, and thus the latter half corresponding to FIG. 36 is illustrated in FIG. 45. FIG. 45 is the same as FIG. 36 except that S266, S269, and S270 are omitted. When a negative determination is made in S263, the process proceeds to S267. When an affirmative determination is made in S267, the process proceeds to S271.

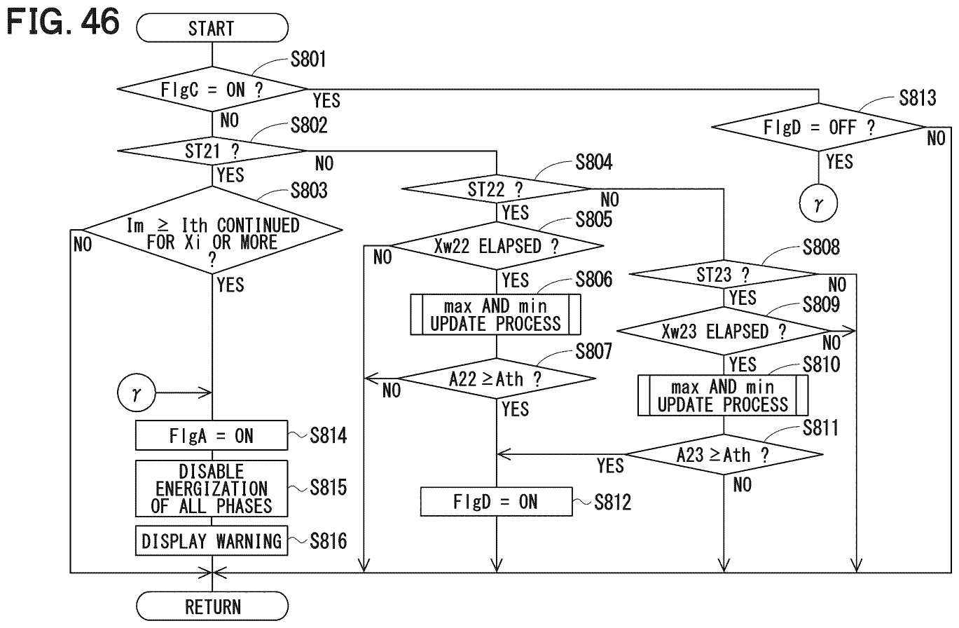

A fault condition determination process will be described with reference to a flowchart of FIG. 46. Processing in S801 is the same as the processing in S501 in FIG. 20. When it is determined that the pre-two-phase-switching energization completion flag FlgC is on (S801: YES), the process proceeds to S813. When it is determined that the pre-two-phase-switching energization completion flag FlgC is off (S801: NO), the process proceeds to S802.

In S802, the abnormality determination unit 52 determines whether the current status is the energization status ST21. When it is determined that the current status is the energization status ST21 (S802: YES), the process proceeds to S803. Processing in S803 is the same as the processing in S503 in FIG. 20. When an affirmative determination is made in S803, the process proceeds to S814. When it is determined that the current status is not the energization status ST21 (S802: NO), the process proceeds to S804.

In S804, the abnormality determination unit 52 determines whether the current status is the energization status ST22. When it is determined that the current status is not the energization status ST22 (S804: NO), the process proceeds to S808. When it is determined that the current status is the energization status ST22 (S804: YES), the process proceeds to S805.

In S805, the abnormality determination unit 52 determines whether the standby time Xw22 has elapsed since the start of the energization status ST22. When it is determined that the standby time Xw22 has not elapsed (S805: NO), the subsequent processing is skipped. When it is determined that the standby time Xw22 has elapsed (S805: YES), the process proceeds to S806 to perform a maximum value and minimum value update process in the energization status ST22.

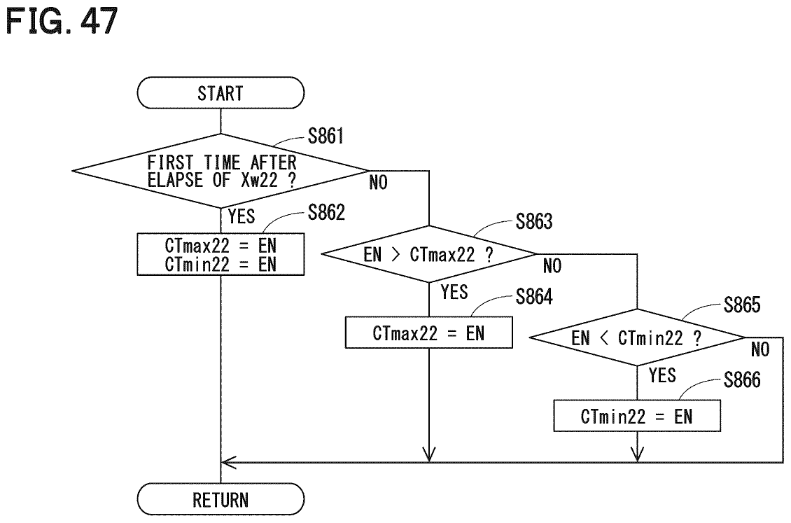

FIG. 47 illustrates a sub-flow of the maximum value and minimum value update process in the energization status ST22. In S861, the abnormality determination unit 52 determines whether it is the first calculation after the elapse of the standby time Xw22. When it is determined that it is the first calculation after the elapse of the standby time Xw22 (S861: YES), the process proceeds to S862 to set the current encoder count value EN as a maximum value CTmax22 and a minimum value CTmin22. When it is determined that it is not the first calculation after the elapse of the standby time Xw22 (S861: NO), the process proceeds to S863.

In S863, the abnormality determination unit 52 determines whether the current encoder count value EN is greater than the maximum value CTmax22. When it is determined that the current encoder count value EN is less than or equal to the maximum value CTmax22 (S863: NO), a value held as the maximum value CTmax22 is not updated, and the process proceeds to S865. When it is determined that the current encoder count value EN is greater than the maximum value CTmax22 (S863: YES), the process proceeds to S864 to update the maximum value CTmax22 to the current encoder count value EN.

In S865, the abnormality determination unit 52 determines whether the current encoder count value EN is less than the minimum value CTmin22. When it is determined that the current encoder count value EN is greater than or equal to the minimum value CTmin22 (S865: NO), a value held as the minimum value CTmin22 is not updated, and the present process is terminated. When it is determined that the current encoder count value EN is less than the minimum value CTmin22 (S865: YES), the minimum value CTmin22 is updated to the current encoder count value EN.

Returning to FIG. 46, in S807 to which the process proceeds after the maximum value and minimum value update process in the energization status ST22, the abnormality determination unit 52 determines whether a vibration amplitude A22 (see formula (3)) is greater than or equal to an amplitude determination threshold Ath. When it is determined that the vibration amplitude A22 is less than the amplitude determination threshold Ath (S807: NO), the subsequent processing is skipped. When it is determined that the vibration amplitude A22 is greater than or equal to the amplitude determination threshold Ath (S807: YES), the process proceeds to S812.

$$A 22 = CT max 22 - CT min 22 \qquad ( 3 )$$

In S808 to which the process proceeds when it is determined that the current status is not the energization status ST22 (S804: NO), the abnormality determination unit 52 determines whether the current status is the energization status ST23. When it is determined that the current status is not the energization status ST23 (S808: NO), the subsequent processing is skipped. When it is determined that the current status is the energization status ST23 (S808: YES), the process proceeds to S809.

In S809, the abnormality determination unit 52 determines whether the standby time Xw23 has elapsed since the start of the energization status ST23. When it is determined that the standby time Xw23 has not elapsed (S809: NO), the subsequent processing is skipped. When it is determined that the standby time Xw23 has elapsed (S809: YES), the process proceeds to S810 to perform a maximum value and minimum value update process in the energization status ST23.

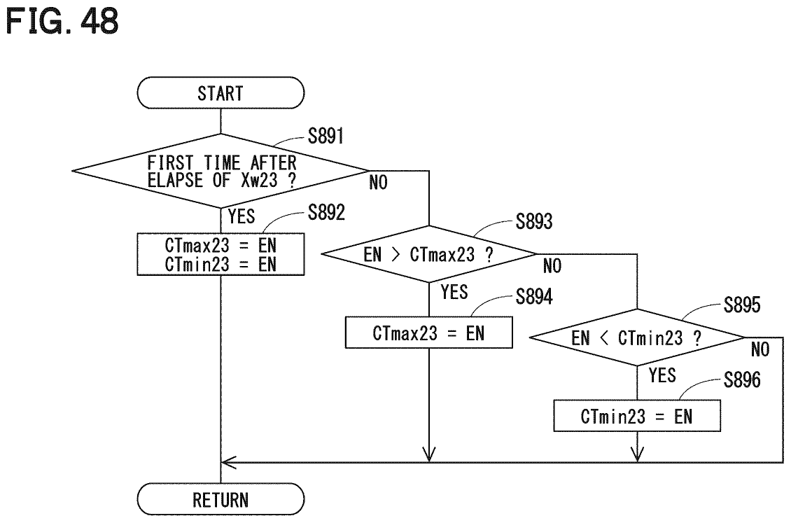

FIG. 48 illustrates a sub-flow of the maximum value and minimum value update process in the energization status ST23. In S891, the abnormality determination unit 52 determines whether it is the first calculation after the elapse of the standby time Xw23. When it is determined that it is the first calculation after the elapse of the standby time Xw23 (S891: YES), the process proceeds to S892 to set the current encoder count value EN as a maximum value CTmax23 and a minimum value CTmin23. When it is determined that it is not the first calculation after the elapse of the standby time Xw23 (S891: NO), the process proceeds to S893.

In S893, the abnormality determination unit 52 determines whether the current encoder count value EN is greater than the maximum value CTmax23. When it is determined that the current encoder count value EN is less than or equal to the maximum value CTmax23 (S893: NO), a value held as the maximum value CTmax23 is not updated, and the process proceeds to S895. When it is determined that the current encoder count value EN is greater than the maximum value CTmax23 (S893: YES), the process proceeds to S894 to update the maximum value CTmax23 to the current encoder count value EN.

In S895, the abnormality determination unit 52 determines whether the current encoder count value EN is less than the minimum value CTmin23. When it is determined that the current encoder count value EN is greater than or equal to the minimum value CTmin23 (S895: NO), a value held as the minimum value CTmin23 is not updated, and the present process is terminated. When it is determined that the current encoder count value EN is less than the minimum value CTmin23 (S895: YES), the minimum value CTmin23 is updated to the current encoder count value EN.

Returning to FIG. 46, in S811 to which the process proceeds after the maximum value and minimum value update process in the energization status ST23, it is determined whether a vibration amplitude A23 (see formula (4)) is greater than or equal to the amplitude determination threshold Ath. The amplitude determination threshold Ath is the same as the value used in S807, but may be different. When it is determined that the vibration amplitude A23 is less than the amplitude determination threshold Ath (S811: NO), the subsequent processing is skipped. When it is determined that the vibration amplitude A23 is greater than or equal to the amplitude determination threshold Ath (S811: YES), the process proceeds to S812.

$$A 23 = CT max 23 - CT min 23 \qquad ( 4 )$$

In S812 to which the process proceeds when it is determined that the vibration amplitude A22 or A23 is greater than or equal to the amplitude determination threshold Ath (S807: YES or S811: YES), the abnormality determination unit 52 identifies the fault occurring in the faulted phase as a wire break fault, and turns on the one-phase wire break fault flag FlgD.

In S813 to which the process proceeds when it is determined that the pre-two-phase-switching energization completion flag FlgC is on (S801: YES), the abnormality determination unit 52 determines whether the one-phase wire break fault flag FlgD is off. When it is determined that the one-phase wire break fault flag FlgD is on (S813: NO), the subsequent processing is skipped. When it is determined that the one-phase wire break fault flag FlgD is off (S813: YES), the abnormality occurring in the faulted phase is identified as a permanent energization fault, and the process proceeds to S814. Processing in S814 to S816 is the same as the processing in S511 to S513 in FIG. 20.

In the present embodiment, the abnormality determination unit 52 identifies the fault as a permanent energization fault when one of the normal phases is energized, and the vibration amplitudes A22 and A23 of the encoder count value after the elapse of the standby times since the start of the energization are less than the amplitude determination threshold Ath. Consequently, a permanent energization fault can be accurately identified. The same effects as those of the above embodiments are achieved.

In the above embodiments, the encoder 13 corresponds to a “rotational position detection unit”, the ECU 40 to the “motor control device”, and the voltage detection circuit 46 to a “voltage detection unit”. The port levels correspond to the “voltage detection values”, and the motor current Im to the “current detection value”. The encoder signal including an A-phase signal and a B-phase signal corresponds to the “rotational position detection value”, the encoder count value to the “rotational position of the motor”, and the vibration amplitudes A22 and A23 to the “amplitudes of the rotational position”.

### Other Embodiments

In the above embodiments, the first fault condition identification process based on the motor current and the second fault condition identification process based on the motor rotational position are performed to identify a permanent energization fault. In another embodiment, using one of the first fault condition identification process and the second fault condition identification process, a permanent energization fault may be identified.

In the first embodiment and the like, before the energization status ST13, which is the first normal phase energization process, the energization status ST12, which is the pre-energization process, is performed. In another embodiment, the pre-energization process may be omitted.

In the above embodiments, the rotation detection unit is an encoder. In another embodiment, for example, a sensor such as a resolver or the like that can detect the rotational position other than an encoder may be used. The current detection unit and the voltage detection unit may also differ in configuration and the like from those of the above embodiments.

In the above embodiments, the motor is a switched reluctance motor. In another embodiment, the motor may be, for example, a DC brushless motor or the like other than a switched reluctance motor. The number of phases of the motor windings may be four or more.

In the above embodiments, the detent plate is provided with the two valleys. In another embodiment, the number of valleys is not limited to two. For example, four valleys corresponding to the P, R, N, and D ranges may be formed. The detent mechanism, the parking lock mechanism, and the like may be different from those of the above embodiments.

In the above embodiments, the motor control device is applied to a shift-by-wire system. In another embodiment, the motor control device may be applied to an in-vehicle system other than a shift-by-wire system, or a motor drive system other than an in-vehicle one.

The present disclosure may be, for example, “the motor control device according to item 3 or 4 in which before the first normal phase energization process, the drive control unit performs pre-energization process to energize one or more of normal phases at least one of which is different from that in the first normal phase energization process”, or “the motor control device according to any one of items 1 to 8 in which the motor is a three-phase motor, and the drive control unit energizes the motor windings of two normal phases to drive the motor when the number of the faulted phases is one, and the permanent energization fault is not identified”.

The control unit and the method thereof described in the present disclosure may be implemented by a dedicated computer provided by configuring a processor programmed to perform one or more of functions embodied by a computer program and a memory. Alternatively, the control unit and the method thereof described in the present disclosure may be implemented by a dedicated computer provided by configuring a processor with one or more dedicated hardware logic circuits. Alternatively, the control unit and the method thereof described in the present disclosure may be implemented by one or more dedicated computers configured with a combination of a processor programmed to perform one or more of functions and a memory and a processor configured with one or more hardware logic circuits. The computer program may be stored in a computer-readable non-transitory tangible recording medium as instructions to be executed by a computer. As described above, the present disclosure is not limited in any way to the above embodiments, and can be implemented in various forms without departing from the gist thereof.

The present disclosure has been described in accordance with the embodiments. However, the present disclosure is not limited to the embodiments and the structures. The present disclosure also encompasses various modifications and variations within the scope of equivalents. Various combinations and modes, and further, other combinations and modes that include only one element or more elements in addition to those of the various combinations and modes, or include elements fewer than those of the various combinations and modes are also within the scope and spirit of the present disclosure.

What is claimed is:

1. A motor control device configured to control driving of a motor including motor windings of three or more phases, the motor control device comprising:
a drive circuit including switching elements configured to turn on and off energization of a corresponding phase of the motor winding; and
a control unit including
a drive control unit configured to control on and off operation of the switching elements, and
an abnormality determination unit configured to perform abnormality determination on an energization path to the motor windings, wherein
the control unit is configured to acquire
a voltage detection value detected by a voltage detection unit configured to detect a phase voltage in the motor windings,
a current detection value detected by a current detection unit configured to detect a current passing through the motor winding, and
a rotational position detection value detected by a rotation detection unit configured to detect a rotational position of the motor,
the abnormality determination unit is configured to identify a faulted phase based on the voltage detection value when the switching elements of all the phases are turned off, and
the abnormality determination unit is configured to identify a permanent energization fault of the faulted phase, based on at least one of
the current detection value when one of the switching elements corresponding to the identified faulted phase is turned on, or
the rotational position detection value when a switching element corresponding to one or more normal phases is turned on.

2. The motor control device according to claim 1, wherein
the abnormality determination unit is configured to identify the permanent energization fault in a case where the current detection value, when the switching element corresponding to the faulted phase is turned on, is greater than or equal to a current determination threshold.

3. The motor control device according to claim 1, wherein
the abnormality determination unit is configured to identify the permanent energization fault, based on an amount of change between
the rotational position of the motor when a first normal phase energization process to energize one or more normal phases is performed and
the rotational position of the motor when a second normal phase energization process to energize one or more normal phases, at least one of which is different from that in the first normal phase energization process, is performed.

4. The motor control device according to claim 3, wherein
the abnormality determination unit is configured to identify the permanent energization fault in a case where a rotational direction at a time of switching from the first normal phase energization process to the second normal phase energization process is different from the rotational direction when all the phases are normal.

5. The motor control device according to claim 3, wherein
the drive control unit is configured to perform, before the first normal phase energization process, a pre-energization process to energize one or more normal phases, at least one of which is different from that in the first normal phase energization process.

6. The motor control device according to claim 3, wherein
the abnormality determination unit is configured to identify the permanent energization fault in a case where the amount of change in the rotational position of the motor is less than a determination threshold when the switching elements of all the normal phases are turned on in the second normal phase energization process.

7. The motor control device according to claim 1, wherein
the abnormality determination unit is configured to identify the permanent energization fault in a case where one of the normal phases is energized, and an amplitude of the rotational position of the motor after elapse of a standby time since a start of energization is less than an amplitude determination threshold.

8. The motor control device according to claim 1, wherein
the rotation detection unit is an encoder, and
the abnormality determination unit is configured to identify the permanent energization fault in a case where an encoder signal pattern when one of the normal phases is energized is a pattern at a time of two-phase energization.

9. The motor control device according to claim 1, wherein
the motor is a three-phase motor, and
the drive control unit is configured to drive the motor by energizing the motor windings of two normal phases when the number of the faulted phases is one and the permanent energization fault is not identified.

10. The motor control device according to claim 9, wherein
when all the phases are normal and a stagnation abnormality in which the rotational position detection value stagnates occurs, the drive control unit is configured to perform open-loop drive to switch energized phases without using the rotational position detection value, instead of feedback control based on the rotational position detection value, and
when the number of the faulted phases is one and the permanent energization fault is not identified, the drive control unit is configured to
drive the motor by energizing the motor windings of two normal phases with the feedback control, and
stop drive control of the motor when the stagnation abnormality occurs.

11. A motor control device configured to control driving of a motor including motor windings of three or more phases, the motor control device comprising:
a plurality of switching elements configured to turn on and off energization of a corresponding phase of the motor winding; and
at least one of (i) a circuit and (ii) a processor having a memory storing computer program code, wherein the at least one of the circuit and the processor having the memory is configured to cause the motor control device to:
control on and off operation of the switching elements;
perform abnormality determination on an energization path to the motor windings;
acquire a voltage detection value of a phase voltage in the motor windings;
acquire a current detection value of a current passing through the motor winding;
acquire a rotational position detection value of a rotational position of the motor;
identify a faulted phase based on the voltage detection value when the switching elements of all the phases are turned off; and
identify a permanent energization fault of the faulted phase, based on at least one of
the current detection value when one of the switching elements corresponding to the identified faulted phase is turned on, or
the rotational position detection value when a switching element corresponding to one or more normal phases is turned on.
